(19) United States
(12) Patent Application Publication
(10) Pub. No.: US 2025/0390643 A1
(43) Pub. Date: Dec. 25, 2025

(54) SYSTEM AND METHOD FOR PRODUCT DESIGN ENHANCEMENT FOR CAD-BASED DISASSEMBLABILITY

(71) Applicant: Wayne State University, Detroit, MI (US)

(72) Inventors: Jeremy L. Rickli, Royal Oak, MI (US); Joao Paulo Jacomini Prioli, Warren, MI (US)

(21) Appl. No.: 19/243,300

(22) Filed: Jun. 19, 2025

Related U.S. Application Data
(60) Provisional application No. 63/662,061, filed on Jun. 20, 2024.

(51) Int. Cl. G06F 30/27; G06F 30/12; G06N 3/042; G06N 3/045; G06N 3/08

(52) U.S. Cl. CPC G06F 30/27; G06F 30/12; G06N 3/042; G06N 3/045; G06N 3/08

(57) ABSTRACT

A method for training a machine learning model using enhanced multilayer direct disassembly networks (MDDNs). The method includes converting MDDNs into knowledge graphs and using them to train a generative and a discriminator component. The generative component produces synthetic disassembly structures, which are evaluated by the discriminator. Feedback from the discriminator is used to refine the generative model, improving the accuracy of disassembly network modeling.

### CROSS REFERENCE TO RELATED APPLICATIONS

This U.S. patent application claims priority under 35 U.S.C. § 119(e) to U.S. Provisional Application 63/662,061, filed on Jun. 20, 2024. The disclosure of this prior application is considered part of the disclosure of this application and is hereby incorporated by reference in its entirety.

### TECHNICAL FIELD

This disclosure generally pertains to a learning-based method for generating an assembly design that enables the removal of a user-selected target component with minimal or reduced disassembly cost.

### BACKGROUND

The following Background is provided solely to help explain the context of this disclosure. Unless specifically stated otherwise, nothing in this section should be interpreted as an admission that it is prior art to the present disclosure.

Assemblies are subject to failure over the course of their operational lifespan. The duration during which a product remains functional is referred to as its “use-life,” while the point at which it is no longer serviceable is termed its “end-of-life.” Upon reaching end-of-life, it is often possible to recover and reuse individual components from the assembly. However, degradation of components over time can significantly hinder or prevent disassembly, thereby limiting the ability to recover reusable parts.

Therefore, there is a need for a better way to design assemblies so that reusable parts can be easily removed at the end of the product's life, with lower disassembly cost.

### SUMMARY

One aspect of the disclosure provides a method for training a machine learning model. The method includes obtaining a plurality of enhanced multilayer direct disassembly networks (MDDNs). The method also includes transforming the plurality of enhanced MDDNs into corresponding knowledge graphs. The method further includes training the machine learning model using the corresponding knowledge graphs.

Implementations of the disclosure may include one or more of the following optional features. In some implementations, training the machine learning model comprises: training a generative component of the machine learning model using the knowledge graphs; and training a discriminator component of the machine learning model using the knowledge graphs. In some implementations, the method further includes generating a synthetic disassembly network structure using the generative component; and classifying the synthetic disassembly network structure using the discriminator component. In some implementations, the method further includes, in response to determining that the discriminator component classified the synthetic disassembly network structure as synthetic, updating one or more parameters of the generative component based on feedback from the discriminator component. In some implementations, the method further includes determining whether the discriminator component misclassified the synthetic disassembly network structure; and, in response to determining that the synthetic disassembly network structure was misclassified, updating one or more parameters of the discriminator component based on feedback from a loss evaluation module.

In some implementations, the plurality of enhanced multilayer direct disassembly networks (MDDNs) includes an enhanced (initial) base MDDN generated by: obtaining a computer-aided design (CAD) assembly file representing an assembly of components; determining pairs of components in contact by calculating surface-to-surface distances below a predefined threshold; generating a contact matrix wherein rows and columns correspond to components, and matrix entries indicate contact relationships; converting the contact matrix into a contact graph comprising nodes representing components and edges representing contact relationships; and generating a collision result comprising part cluster information by applying a machine learning clustering algorithm to the contact graph.

In some implementations, the plurality of enhanced multilayer direct disassembly networks (MDDNs) includes a first enhanced simulated MDDN generated by: obtaining the computer-aided design (CAD) assembly file representing an assembly of components; determining pairs of components in contact by calculating surface-to-surface distances below a predefined threshold; determining non-separable component pairs based on first degradation data; generating a first contact matrix wherein rows and columns correspond to components, and matrix entries indicate contact relationships; converting the first contact matrix into a first contact graph comprising nodes representing components and edges representing contact relationships; and generating a first collision result comprising part cluster information by applying a machine learning clustering algorithm to the first contact graph, wherein non-separable component pairs are represented as a single component in the first contact matrix.

In some implementations, the plurality of enhanced multilayer direct disassembly networks (MDDNs) includes a second enhanced simulated MDDN generated by: obtaining the computer-aided design (CAD) assembly file representing an assembly of components; determining pairs of components in contact by calculating surface-to-surface distances below a predefined threshold; determining non-separable component pairs based on second degradation data, wherein the second degradation data is different from the first degradation data; generating a second contact matrix wherein rows and columns correspond to components, and matrix entries indicate contact relationships; converting the second contact matrix into a second contact graph comprising nodes representing components and edges representing contact relationships; and generating a second collision result comprising part cluster information by applying a machine learning clustering algorithm to the second contact graph, wherein non-separable component pairs are represented as a single component in the second contact matrix.

According to a further aspect of the disclosure, a method for product design enhancement for CAD-based disassemblability includes: obtaining a sequence of disassembly possibilities through collision tests; transforming the disassembly possibilities into a direct disassembly network; obtaining a plurality of enhanced multilayer direct disassembly networks (MDDNs); transforming the plurality of enhanced MDDNs into corresponding knowledge graphs; training the machine learning model using the generated knowledge graphs.

The implementations discussed above likewise apply, mutatis mutandis, to this further aspect.

Another aspect of the disclosure provides a system for training a machine learning model. The system includes data processing hardware and memory hardware in communication with the data processing hardware. The memory hardware stores instructions that, when executed on the data processing hardware, cause the data processing hardware to perform operations. The operations include obtaining a plurality of enhanced multilayer direct disassembly networks (MDDNs). The operations also include transforming the plurality of enhanced MDDNs into corresponding knowledge graphs. The operations further include training the machine learning model using the corresponding knowledge graphs.

Implementations of the disclosure may include one or more of the following optional features. In some implementations, training the machine learning model comprises: training a generative component of the machine learning model using the knowledge graphs; and training a discriminator component of the machine learning model using the knowledge graphs. In some implementations, the operations further comprise: generating a synthetic disassembly network structure using the generative component; and classifying the synthetic disassembly network structure using the discriminator component. In some implementations, the operations further comprise, in response to determining that the discriminator component classified the synthetic disassembly network structure as synthetic, updating one or more parameters of the generative component based on feedback from the discriminator component. In some implementations, the operations further comprise determining whether the discriminator component misclassified the synthetic disassembly network structure; and, in response to determining that the synthetic disassembly network structure was misclassified, updating one or more parameters of the discriminator component based on feedback from a loss evaluation module.

In some implementations, the plurality of enhanced multilayer direct disassembly networks (MDDNs) includes an enhanced (initial) base MDDN generated by: obtaining a computer-aided design (CAD) assembly file representing an assembly of components; determining pairs of components in contact by calculating surface-to-surface distances below a predefined threshold; generating a contact matrix wherein rows and columns correspond to components, and matrix entries indicate contact relationships; converting the contact matrix into a contact graph comprising nodes representing components and edges representing contact relationships; and generating a collision result comprising part cluster information by applying a machine learning clustering algorithm to the contact graph.

In some implementations, the plurality of enhanced multilayer direct disassembly networks (MDDNs) includes a first enhanced simulated MDDN generated by: obtaining the computer-aided design (CAD) assembly file representing an assembly of components; determining pairs of components in contact by calculating surface-to-surface distances below a predefined threshold; determining non-separable component pairs based on first degradation data; generating a first contact matrix wherein rows and columns correspond to components, and matrix entries indicate contact relationships; converting the first contact matrix into a contact graph comprising nodes representing components and edges representing contact relationships; and generating a first collision result comprising part cluster information by applying a machine learning clustering algorithm to the first contact graph, wherein non-separable component pairs are represented as a single component in the first contact matrix.

In some implementations, the plurality of enhanced multilayer direct disassembly networks (MDDNs) includes a second enhanced simulated MDDN generated by: obtaining the computer-aided design (CAD) assembly file representing an assembly of components; determining pairs of components in contact by calculating surface-to-surface distances below a predefined threshold; determining non-separable component pairs based on second degradation data, wherein the second degradation data is different from the first degradation data; generating a second contact matrix wherein rows and columns correspond to components, and matrix entries indicate contact relationships; converting the second contact matrix into a second contact graph comprising nodes representing components and edges representing contact relationships; and generating a second collision result comprising part cluster information by applying a machine learning clustering algorithm to the second contact graph, wherein non-separable component pairs are represented as a single component in the second contact matrix.

Another aspect of the disclosure provides a system for generating computer-aided design (CAD) assembly files. The system includes a memory storing instructions, and a processor configured to execute the instructions to: receive input data comprising a multilayer direct disassembly network (MDDN) and a target part specification; process the MDDN and the target part specification using a generative model to produce a revised MDDN optimized for accessibility of the target part; convert the revised MDDN into a CAD assembly file; and present the CAD assembly file to a user via a user interface.

Implementations of the disclosure may include one or more of the following optional features. In some implementations, the user interface is further configured to receive user feedback regarding the CAD assembly file. In some implementations, the generative model is updated or retrained based on the received user feedback to improve future design generation. In some implementations, the generative model is initially trained by a plurality of enhanced MDDNs.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. The claimed subject matter is not limited to implementations that solve any or all disadvantages noted in the Background.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 is a schematic diagram of a system for training a machine learning model to generate multilayer direct disassembly networks (MDDNs), in accordance with some implementations of the present disclosure.

FIG. 2A illustrates a collision tester configured to generate collision results, including part cluster information, through geometric analysis of computer-aided design (CAD) assemblies, in accordance with some implementations of the present disclosure.

FIG. 2B depicts example interference results generated by the collision tester, comprising a base interference matrix that represents spatial relationships between assembly components, in accordance with some implementations of the present disclosure.

FIG. 3A illustrates an assembly-level interference matrix and sub-assembly matrices derived from the base interference matrix by an interference analyzer, in accordance with some implementations of the present disclosure.

FIG. 3B shows a process for generating a base multilayer direct disassembly network (MDDN) using the interference analyzer, demonstrating hierarchical network construction from interference matrices, in accordance with some implementations of the present disclosure.

FIG. 3C provides a detailed view of the base MDDN, illustrating multiple disassembly paths and node-edge relationships within the network structure, in accordance with some implementations of the present disclosure.

FIG. 4 illustrates a portion of an enhanced MDDN augmented by an augmenter, demonstrating attribute enrichment for nodes and edges, in accordance with some implementations of the present disclosure.

FIG. 5A shows a collision tester configured to generate collision results, including degradation-aware part cluster information, from a CAD assembly file and component degradation data, in accordance with some implementations of the present disclosure.

FIG. 5B depicts the collision tester generating interference results, including a degradation-modified base interference matrix, in accordance with some implementations of the present disclosure.

FIG. 6A illustrates an assembly-level interference matrix and sub-assembly matrices derived from the degradation-modified base interference matrix, in accordance with some implementations of the present disclosure.

FIG. 6B depicts a simulated MDDN constructed from the assembly-level interference matrix and sub-assembly matrices, demonstrating degradation-adapted disassembly paths, in accordance with some implementations of the present disclosure.

FIG. 7 illustrates a machine learning architecture comprising a generative model and a discriminator model configured for adversarial training of disassembly networks, in accordance with some implementations of the present disclosure.

FIG. 8 shows a system diagram of a design generator for converting MDDNs into CAD assembly files through a generative model and user feedback integration, in accordance with some implementations of the present disclosure.

FIG. 9 is a flowchart of a method for extracting part cluster information from CAD assembly files using machine learning-based contact analysis, in accordance with some implementations of the present disclosure.

FIG. 10 is a flowchart of a process for generating MDDNs through hierarchical interference matrix analysis, in accordance with some implementations of the present disclosure.

FIG. 11 is a flowchart of a method for enhancing MDDNs with node and edge attributes, including disassembly operations and cost data, in accordance with some implementations of the present disclosure.

FIG. 12 is a flowchart of a method for generating degradation-enhanced MDDNs with probabilistic cost analysis, in accordance with some implementations of the present disclosure.

FIG. 13 is a flowchart of a method for training generative AI models using adversarial learning to produce optimized disassembly networks, in accordance with some implementations of the present disclosure.

FIG. 14 is a flowchart of a method for iterative CAD assembly generation using MDDNs and user feedback integration, in accordance with some implementations of the present disclosure.

FIG. 15 is a schematic diagram of an example computing device implementing the disclosed systems and methods, in accordance with some implementations of the present disclosure.

Like reference symbols in the various drawings indicate like elements.

### DETAILED DESCRIPTION

This disclosure relates to systems and methods for automated disassembly planning and design optimization in computer-aided design (CAD) environments. In particular, the disclosure provides a machine learning-based framework for generating multilayer direct disassembly networks (MDDNs) that model feasible disassembly sequences, account for component degradation, and enable cost-effective product lifecycle management. The disclosed system utilizes a processing platform that analyzes CAD assembly files, identifies part clusters and interference relationships, and constructs hierarchical network representations. These networks are enhanced with node and edge attributes reflecting operational, temporal, and degradation-related factors. Advanced neural network architectures, including generative adversarial models, are trained to learn optimal disassembly strategies and generate new, disassembly-friendly assembly designs. The disclosure further supports iterative design refinement through user feedback and enables integration with CAD tools for seamless transition from conceptual planning to manufacturable product assemblies.

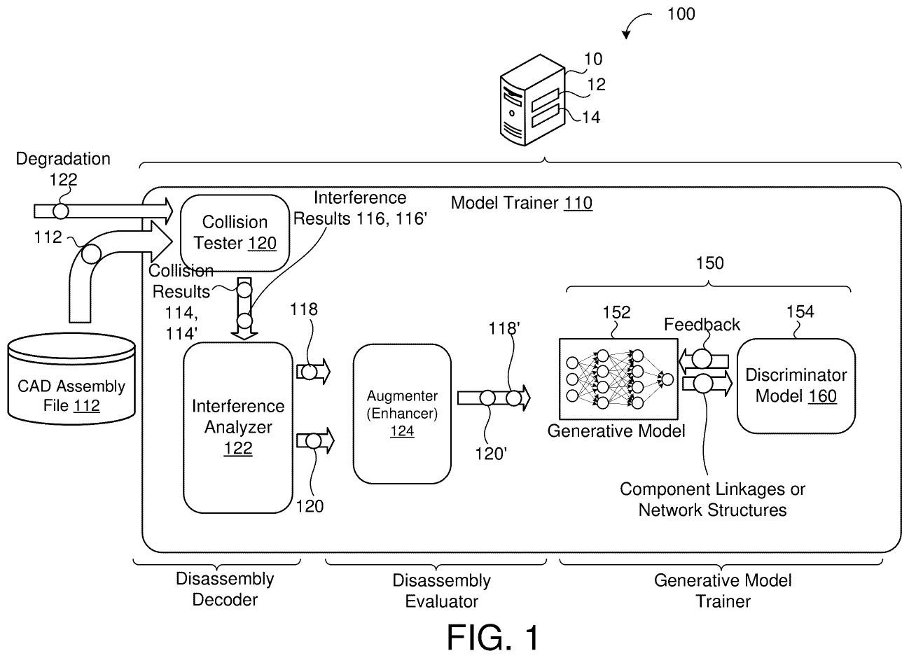

Referring to FIG. 1, in some implementations, an example system 100 includes a processing system 10. The processing system 10 may be a single computer, multiple computers, or a distributed system (e.g., a cloud environment) having fixed or scalable/elastic computing resources 12 (e.g., data processing hardware) and/or storage resources 14 (e.g., memory hardware). The processing system 10 executes a model trainer 110, which is implemented as software, firmware, hardware, or any combination thereof.

The model trainer 110 is operable to train a machine learning model 150, which may include, but is not limited to, a generative adversarial network (GAN), a reinforcement learning model, or other neural network architectures. The machine learning model 150 is trained to generate multilayer direct disassembly networks (MDDNs) in response to input data or requests. Such input data may include, for example, identification of a target component to be disassembled, degradation information, maintenance history, or environmental exposure data.

In some implementations, the model trainer 110 trains both a generator (generative model 152) and a discriminator (discriminator model 154) for the machine learning model 150. In some implementations, the model trainer 110 performs trainings (e.g., initial trainings) using knowledge graphs derived from an enhanced base MDDN 118′ and one or more enhanced simulated MDDNs 120′. In some implementations, these knowledge graphs are stored in the storage resource 14 and may be indexed or organized for efficient retrieval.

In some implementations, the enhanced base MDDN 118′ comprises a directed network structure that represents a plurality of possible disassembly sequences for an assembly, as well as the disassembly cost, time, or risk associated with each sequence. In some implementations, each of the enhanced simulated MDDNs 120′ comprises a directed network structure that represents a plurality of possible disassembly sequences for an assembly, as well as the disassembly cost, time, or risk associated with each sequence. In some implementations, unlike the enhanced based MDDN 118′, each of the enhanced simulated MDDNs 120′ is determined based on specific degradation information such as various degradation conditions (e.g., wear, tear, material degradation effects like rust). The network nodes of the enhanced MDDN 118′ and simulated MDDNs 120′ may represent components or subassemblies for disassembly, while the edges may represent feasible disassembly actions, times associated with the disassembly action or disassemble costs.

The model trainer 110 is configured to generate the enhanced MDDN 118′ and the one or more enhanced simulated MDDNs 120′ based on a computer-aided design (CAD) assembly file 112 corresponding to a physical or virtual assembly. The CAD assembly file 112 may include geometric, topological, material, and metadata information for each component and its relationships within the assembly.

The model trainer 110 may obtain the CAD assembly file 112 from the storage resources 14, an external database, a product lifecycle management (PLM) system, or another device configured to store or provide the CAD assembly file 112.

In some implementations, the model trainer 110 comprises a collision tester 120, which is configured to analyze the CAD assembly file 112 and generate collision results 114. The collision results 114 may include part cluster information, spatial overlap data, or identification of potential collision pairs among components during disassembly. The collision tester 120 may further generate interference results, such as a base interference matrix, by evaluating spatial, mechanical, or functional interferences using the CAD assembly file 112.

In some implementations, the model trainer 110 comprises an interference analyzer 122 configured to generate a base MDDN 118 based on the interference results 116 (e.g., interference matrix) and the collision results 114 (e.g., part cluster information).

In some implementations, the interference analyzer 122 updates the base interference matrix based on the part cluster information. In some implementations, based on the base interference matrix, the part cluster information, and the updated interference matrix, interference analyzer 122 generates an assembly level interference matrix and one or more sub level interference matrices. Based on the assembly level interference matrix and the one or more sub level interference matrices, the interference analyzer 122 generates the base MDDN 118, which indicates feasible disassembly paths and their associated constraints (e.g., disassembly cost).

In some implementations, the model trainer 110 comprises an augmenter 124 configured to enhance the base MDDN 118. The augmenter 124 may update each node of the base MDDN 118 with node attributes, such as component type, material, degradation state, or historical maintenance data. The augmenter 124 may update each edge of the base MDDN 118 with edge attributes, such as estimated disassembly time, required tools, safety risks, or cost metrics. As a result, the augmenter 124 produces the enhanced MDDN 118′, which provides a more comprehensive and actionable representation of the disassembly process.

In some implementations, the collision tester 120, which is configured to analyze the CAD assembly file 112 and degradation information 122 and generate collision results 114′. The collision results 114′ may include part cluster information, spatial overlap data, or identification of potential collision pairs among components during disassembly. The collision tester 120 may further generate interference results 116′, such as a base interference matrix, by evaluating spatial, mechanical, or functional interferences using the CAD assembly file 112.

In some implementations, the interference analyzer 122 configured to generate one or more simulated MDDNs 120 based on the interference results 116′ (e.g., interference matrix), the collision results 114′ (e.g., part cluster information), and the degradation information 122 (e.g., degradation conditions such as wear, tear, material degradation effects like rust).

In some implementations, the interference analyzer 122 updates the interference matrix based on the part cluster information (and the degradation information). In some implementations, based on the interference matrix, the part cluster information, and the updated interference matrix, interference analyzer 122 generates an assembly level interference matrix and one or more sub level interference matrices. Based on the assembly level interference matrix and the one or more sub level interference matrices, the interference analyzer 122 generates the simulated MDDN 120, which shows feasible disassembly paths and their associated constraints (e.g., disassembly cost). In some implementations, the interference analyzer can generates various MDDNs 120 under various degradation conditions.

In some implementations, the augmenter 124 configured to enhance the simulated MDDNs 120. The augmenter 124 may update each node of the simulated MDDNs 120 with (simulated) node attributes and each edge with (simulated) edge attributes. This process produces the enhanced simulated MDDNs 120′.

As discussed above, in some implementations, the model trainer 110 is configured to generate the generator (generative model 152) and the discriminator (discriminator model 154) of the machine learning model 150 based on knowledge graphs constructed from the enhanced MDDN 118′ and the one or more enhanced simulated MDDNs 120′. The knowledge graphs may be used to encode structural, temporal, and cost-related information, enabling the machine learning model 150 to learn optimal or near-optimal disassembly strategies for a variety of assemblies and operational scenarios.

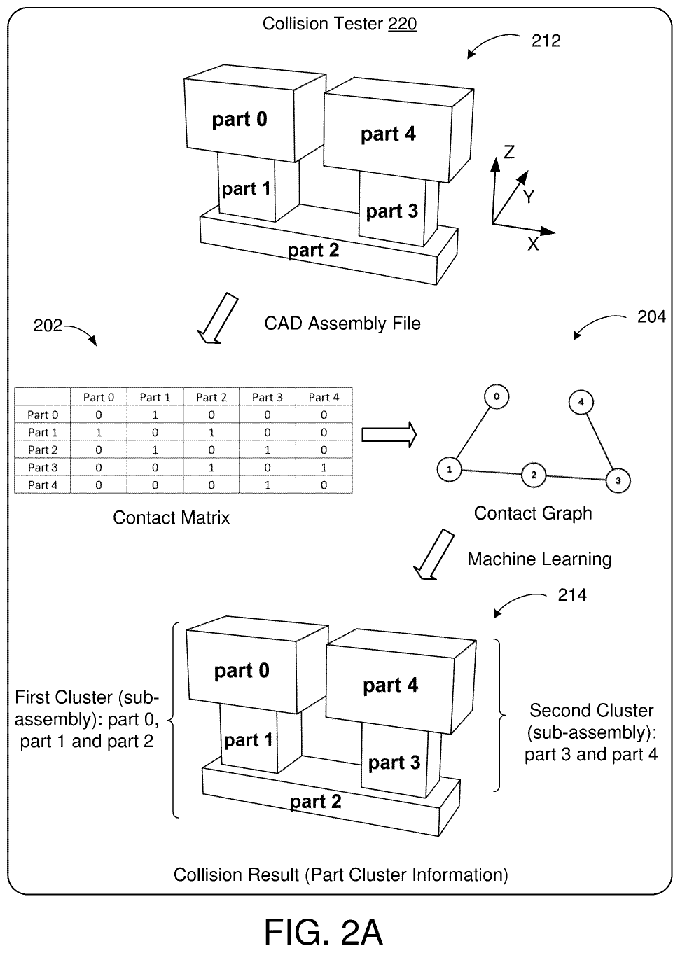

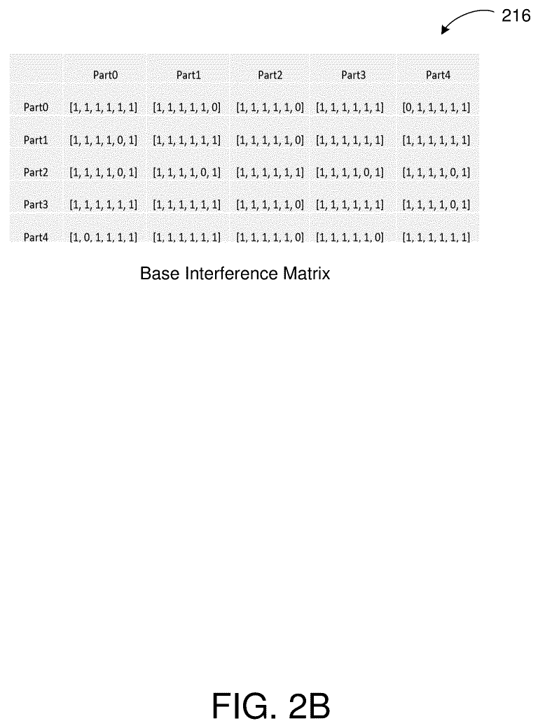

FIG. 2A illustrates a collision tester 220 configured to generate collision results 214 (e.g., part cluster information) in accordance with some implementations of this disclosure.

As illustrated in FIG. 2A, in some implementations, the collision tester 220 is configured to determine which parts within a computer-based model of an assembly (CAD assembly file 212) are physically touching or in contact with each other. In this context, a “digital assembly” refers to a virtual representation of a real-world product or system, created using specialized computer-aided design (CAD) software. This digital assembly (CAD assembly file 212 in this example) contains all the necessary information about each part's shape, size, and how the parts are positioned relative to one another, but exists as data on a computer rather than as a physical object. In some implementations, the collision tester 220 is further configured to determine one or more sub-assemblies (clusters) within the assembly.

The collision tester 220 receives the CAD assembly file 212, such as a STEP, STP, or STL file. These files are standard formats used to describe the geometry and arrangement of each part in the assembly. The CAD assembly file 212 provides detailed information about each component, including its structure and how it fits with other components in the digital model.

Once the CAD assembly file 212 is loaded, the collision tester 220 analyzes the digital assembly in the CAD assembly file 212 to identify every individual solid body present. This involves exploring the file's structure, which means systematically examining the organizational hierarchy within the CAD assembly file 212. In a typical CAD assembly file, parts and sub-assemblies are organized in a tree-like structure, where a top-level assembly may contain multiple sub-assemblies or parts, and each sub-assembly may further contain additional parts or features. The collision tester 220 navigates through this hierarchy-starting from the top-level assembly and moving down through any sub-assemblies-until it locates all the distinct solid bodies. Each solid body represents a separate, physical part in the real-world assembly.

By traversing this hierarchy, the collision tester 220 ensures that even if several parts are grouped together or nested within sub-assemblies, each one is individually identified and considered for contact analysis. This thorough examination is necessary to accurately determine which parts may be in contact within the digital assembly. In this example, the collision tester 220 determines that there are five parts or components (part 0, part 1, part 2, part 3, and part 4) within the assembly in the CAD assembly file 212.

After identifying all the individual parts in the digital assembly, the collision tester 220 examines every possible pair of parts. For each pair, it determines (e.g., calculates) the minimum distance between their surfaces. If this minimum distance is less than a very small, predefined threshold (for example, 0.0001 units), the collision tester 220 determines that these two parts are in direct contact. This threshold helps account for minor imperfections in the digital model while still accurately identifying real physical contact if the assembly were built in the real world.

The results of these pairwise checks are organized into a two-dimensional data structure known as a contact matrix 202. In this matrix 202, each row and column corresponds to a specific part in the digital assembly. If two parts are found to be in contact, the corresponding entry in the matrix is set to 1; if they are not in contact, the entry is set to 0. The diagonal entries, which would represent a part's contact with itself, are typically set to 0 or another placeholder value.

Once the contact matrix 202 is fully populated, the collision tester 220 may further process or convert it into other formats, such as a graph structure (contact graph 204 in this example). In this example, the contact graph 204 shows that the part 0 is in contact with the part 1, the part 1 is in contact with the part 2, the part 2 is in contact with the part 3, and the part 3 is in contact with the part 4.

In some implementations, the collision tester 220 is configured to determine several parts that are grouped together or nested within sub-assemblies (also referred to as clusters) in the assembly by analyzing the graph structure (contact graph 204 in this example) using a machine learning model, such as a community detection model.

As a result, the collision tester 220 determine which parts or components are grouped together or nested within sub-assemblies and generates the collision results 214 (part cluster information). In this example, the part 0, the part 1, and the part 2 associate with a first cluster or sub-assembly, and the part 3 and the part 4 associate with a second cluster or sub-assembly.

FIG. 2B illustrates an example interference results 216 (base interference matrix in this example) generated by the collision tester 220 in accordance with some implementations of this disclosure.

As illustrated in FIG. 2B, in some implementations, the collision tester 220 is configured to generate interference results 216, such as a base interference matrix.

The base interference matrix 216 represents the assembly in a tabular format, where each row and each column correspond to individual parts within the assembly. Each cell of the matrix contains a string representation of a list comprising six binary elements (e.g., [0,0,1,0,0,0]). Each element in the list corresponds to one of the six degrees of freedom (DOF) for disassembly: positive X, negative X, positive Y, negative Y, positive Z, and negative Z directions. In some implementations, the base interference matrix 216 may be extended to represent more than six degrees of freedom by including additional values in the list, thereby enabling computation of interference in additional directions. In some implementations, other vector directions may be used instead of, or in addition to, the standard positive and negative X, Y, and Z directions.

A value of 0 in a given position within the list indicates that no interference exists if part i is moved in the corresponding direction while part j remains stationary. Conversely, a value of 1 indicates that interference is present in that direction. The diagonal cells of the interference matrix, which correspond to a part's relationship with itself, may represent the part's own properties or may be set to a default blockage state (e.g., all elements set to 1) by certain functions, particularly in cases where subassemblies are formed.

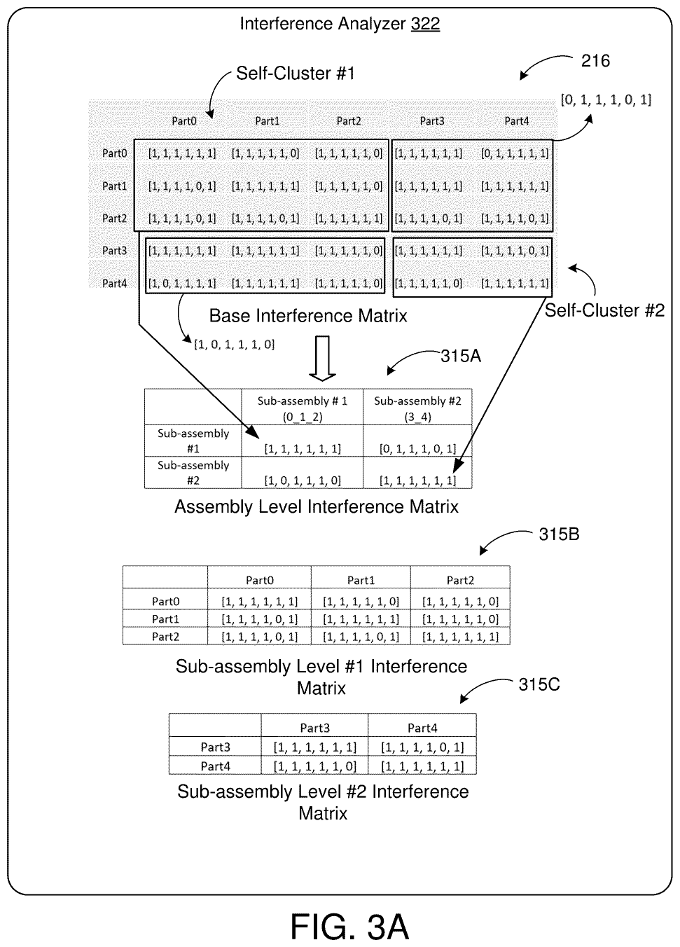

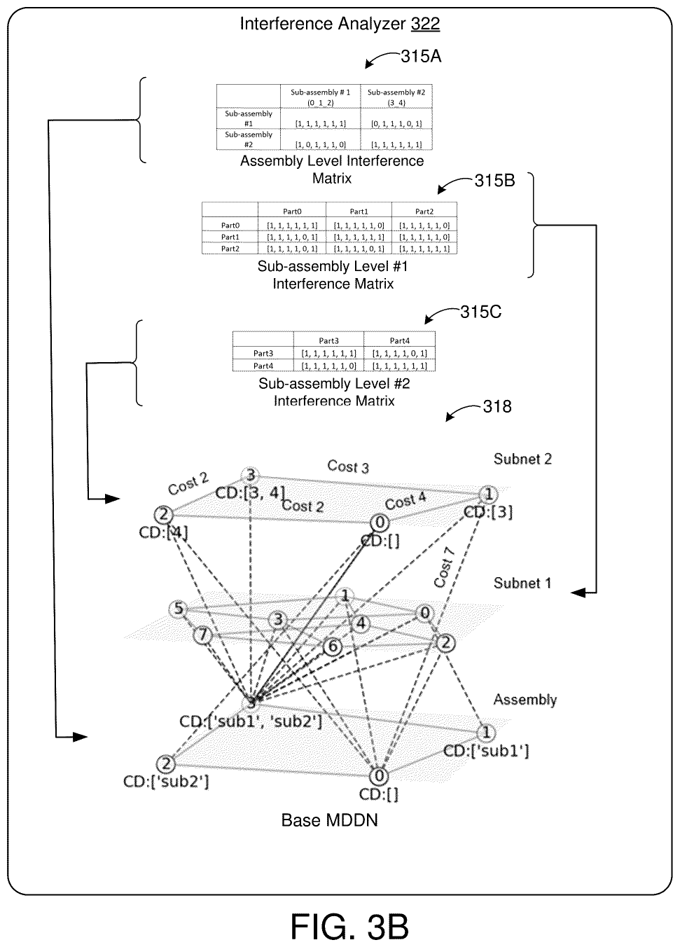

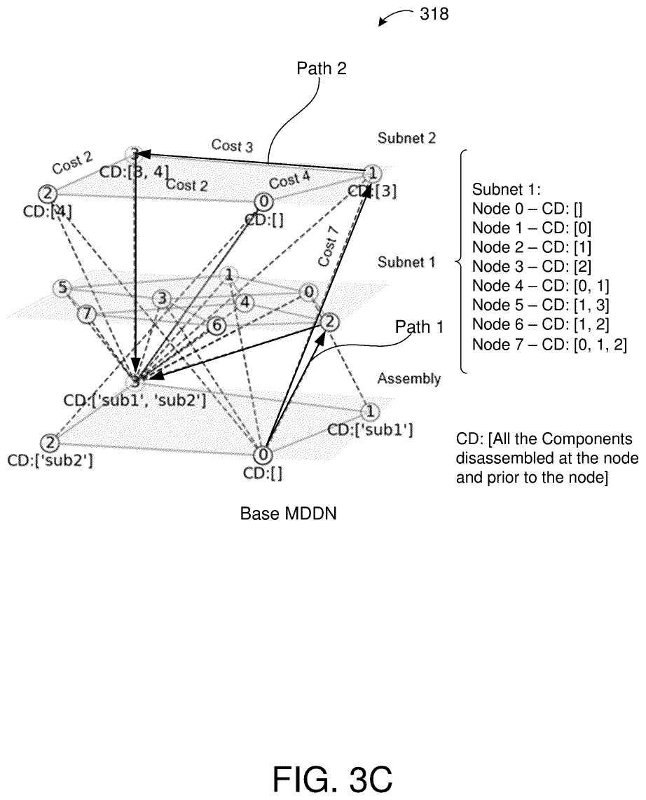

FIG. 3A illustrates an example assembly level interference matrix 315A, one or more sub-assembly matrices (sub-assembly level #1 interference matrix 315B and sub-assembly level interference matrix #2 315C in this example) based on the base interference matrix 216 from FIG. 2B by an interference analyzer 322 in accordance with some implementations of this disclosure.

As illustrated in FIG. 3A, based on the collision results (e.g., part cluster information 214), the interference analyzer 322 is configured to identify sub-assemblies, (also referred to as clusters) within the assembly in the CAD assembly file 210. In this example, the parts 0, 1, and 2 are grouped as the first sub-assembly (cluster #1), while parts 3 and 4 are grouped as the second sub-assembly (cluster #2).

As shown in FIG. 3A, the interference analyzer 322 generates a separate interference matrix for each sub-assembly. Specifically, the interference analyzer 322 generates a sub-assembly level #1 interference matrix 315B by extracting the portion of the base interference matrix 216 that corresponds to cluster #1. This means that the matrix 315B includes only those cells where both the columns and the rows are associated with parts 0, 1, or 2. Similarly, the interference analyzer 322 generates a sub-assembly level #2 interference matrix 315C by extracting the portion of the base interference matrix 216 that corresponds to cluster #2, including only those cells where both the columns and the rows are associated with parts 3 or 4.

In some implementations, the interference analyzer 322 is configured to make the base interference matrix 216A easier to work with by grouping together certain cells based on how the parts are clustered. The goal is to simplify the matrix by merging cells that represent similar interference relationships between groups of parts, also known as clusters.

In this example, the parts 0, 1, and 2 are grouped together as cluster #1, and the parts 3 and 4 are grouped together as cluster #2. The interference analyzer 322 looks at the matrix and identifies all the cells where the columns correspond to parts 3 or 4 (from cluster #2) and the rows correspond to the parts 0, 1, or 2 (from cluster #1). Since these parts belong to different clusters, the tester checks which directions of interference are relevant between these two groups. In this case, it is determined that interference occurs in vector directions 2, 3, 4, and 6 (since the values for these directions are “1”). As a result, the tester merges all these relevant cells into a single, combined vector, which can be represented as [0, 1, 1, 1, 0, 1]. This vector summarizes the interference from cluster #2 (parts 3 and 4) to cluster #1 (parts 0, 1, and 2) in the specified directions.

Similarly, in this example, the interference analyzer 322 also looks at the reverse relationship. This time, it focuses on the cells where the columns are the parts 0, 1, or 2 (from cluster #1) and the rows are the parts 3 or 4 (from cluster #2). Again, the interference analyzer 322 checks which directions show interference between these clusters. Here, interference is found in vector directions 1, 3, 4, and 5 (since the values for these directions are “1”). The interference analyzer 322 then merges these cells into another combined vector, represented as [1, 0, 1, 1, 1, 0]. This vector captures the interference from cluster #1 (parts 0, 1, and 2) to cluster #2 (parts 3 and 4) in those directions.

By merging these cells based on cluster membership and interference directions, the interference analyzer 322 reduces the complexity of the interference matrix. As a result, the interference analyzer 322 generates the assembly level interference matrix 315A.

FIG. 3B illustrates a process for generating the base multilayer direct disassembly network (MDDN) 318 using the interference analyzer 322, in accordance with some implementations of this disclosure.

As shown in FIG. 3B, the interference analyzer 322 constructs the MDDN 318 by creating nodes based on different levels of interference matrices. Specifically, the interference analyzer 322 generates nodes for the assembly-level network using the assembly-level interference matrix 315A, nodes for the sub-assembly level #1 network using the sub-assembly level #1 interference matrix 315B, and nodes for the sub-assembly level #2 network using the sub-assembly level #2 interference matrix 315C. Each node represents a state in which certain parts have been disassembled either at that node or prior to reaching that node.

The interference analyzer 322 also generates edges that connect these nodes. Each edge represents a possible disassembly path, showing the sequence in which parts or sub-assemblies can be removed. Therefore, each node corresponds to a specific set of parts or sub-assemblies to be disassembled at that stage in the network.

FIG. 3C provides a more detailed view of the base MDDN 318, illustrating how different disassembly paths can be represented within the network.

For example, Path 1 in the MDDN 318 demonstrates a scenario where, at the “0” node of the assembly-level network, no parts have been disassembled. At the “2” node of the sub-assembly level #1 network, the part 1 is removed from cluster #1. At the “3” node of the assembly-level network, the remaining parts of cluster #1 and the cluster #2 are disassembled.

Similarly, Path 2 in FIG. 3C illustrates another scenario where, at the “0” node of the assembly-level network, no parts have been disassembled. At the “2” node of the sub-assembly level #2 network, the part 3 is removed from cluster #2. At the “3” node of the sub-assembly level #2 network, the part 4 is removed from cluster #2-resulting removal of the cluster #2. Finally, at the “3” node of the assembly-level network, the cluster #1 is disassembled.

These examples show how the MDDN 318 enables systematic planning for disassembly by mapping out all possible sequences for removing parts and sub-assemblies across multiple hierarchical levels.

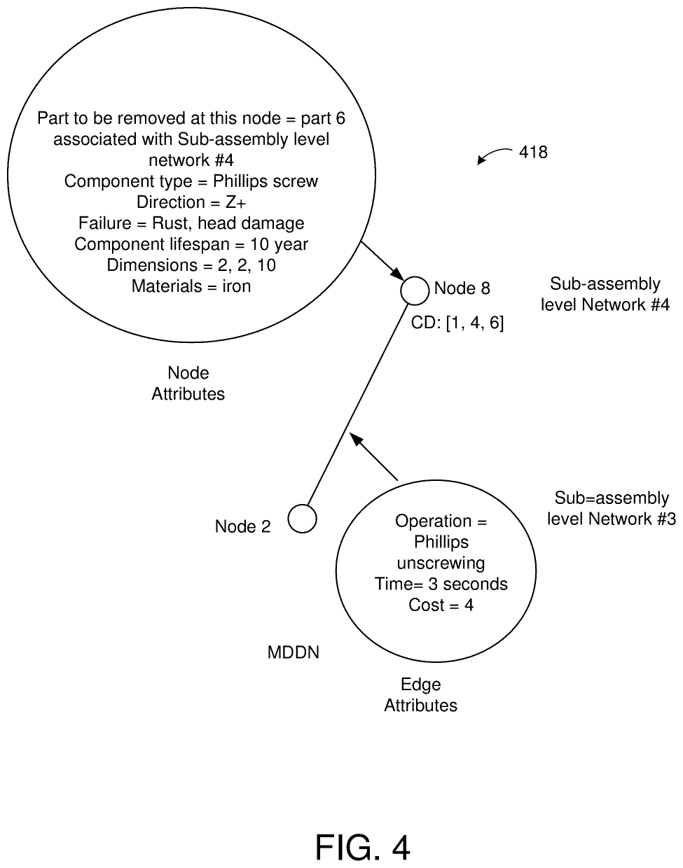

FIG. 4 illustrates a portion of an example enhanced multilayer direct disassembly network (MDDN) 418, which has been augmented by an augmenter 424 in accordance with some implementations of the present disclosure.

As depicted in FIG. 4, in this example, the augmenter 424 assigns various node attributes to node 8, which is associated with sub-assembly level network #4. In this example, the node attributes assigned include, but are not limited to, component type, disassembly direction, potential for disassembly failure, component lifespan, component dimensions, and component material. Additionally, in this example, the augmenter 424 assigns edge attributes to the edge connecting node 8 and node 2, which are associated with sub-assembly level network #3. In this example, the edge attributes include the type of disassembly operation required, the estimated time to perform the operation, and the associated cost.

This approach enables the MDDN 418 to represent both component (or sub-assembly)-specific and operation-specific information, thereby supporting more comprehensive and accurate analysis of disassembly processes within the network.

In some implementations, the augmenter 424 is configured to assign specific attributes to both the edges and nodes of the multilayer direct disassembly network (MDDN). These attributes enrich the MDDN with operational, temporal, and contextual information, transforming it from a purely structural network into a weighted, information-rich graph suitable for advanced disassembly analysis and optimization.

In some implementations, for each edge in the MDDN, the augmenter assigns an attribute that specifies the type of physical operation required for the corresponding disassembly step. Examples of such operations include “unscrew Phillips head,” “unclip,” “linear pull,” “rotate and pull,” or “cut.” The operation type can be determined by directly retrieving the information from a product ontology or a database that links component types to standard disassembly operations. If this information is not available, the augmenter 424 is further configured to infer the likely operation by matching the component or interface type to similar types previously encountered in other MDDNs, utilizing a knowledge base or a machine learning model trained on historical disassembly data.

In some implementations, in addition to the operation type, the augmenter 424 assigns attributes to each edge that quantify the resources required for the disassembly operation, such as time, cost, or both. Where available, this information can be directly input from standard databases, time studies, or user input. If such data are not directly available, the augmenter 424 estimates the time and/or cost as a function of the disassembly travel distance. To accomplish this, the augmenter 424 extracts the dimensions of each component's boundary box from the CAD file (e.g., CAD assembly file), typically using contact matrix analysis. The disassembly travel distance is then calculated as the dimension of the boundary box in the direction of disassembly. For example, if a part is 50 mm long in the X-direction and is disassembled by pulling in the +X direction, the travel distance is 50 mm. This calculated travel distance is assigned as an attribute to the corresponding edge in the MDDN. The actual disassembly time can then be derived from this distance using robotic parameters such as average speed, with time calculated as travel distance divided by speed plus any fixed operation times. Cost can be derived from time, for example, by multiplying the calculated time by the robot operating cost per unit time.

In some implementations, the augmenter 424 is also configured to assign attributes to nodes. These node attributes may include the state of the part, such as degradation level or spatial relationship, as well as information about sub-assembly membership, such as whether the part belongs to cluster #1 or cluster #2, for an example.

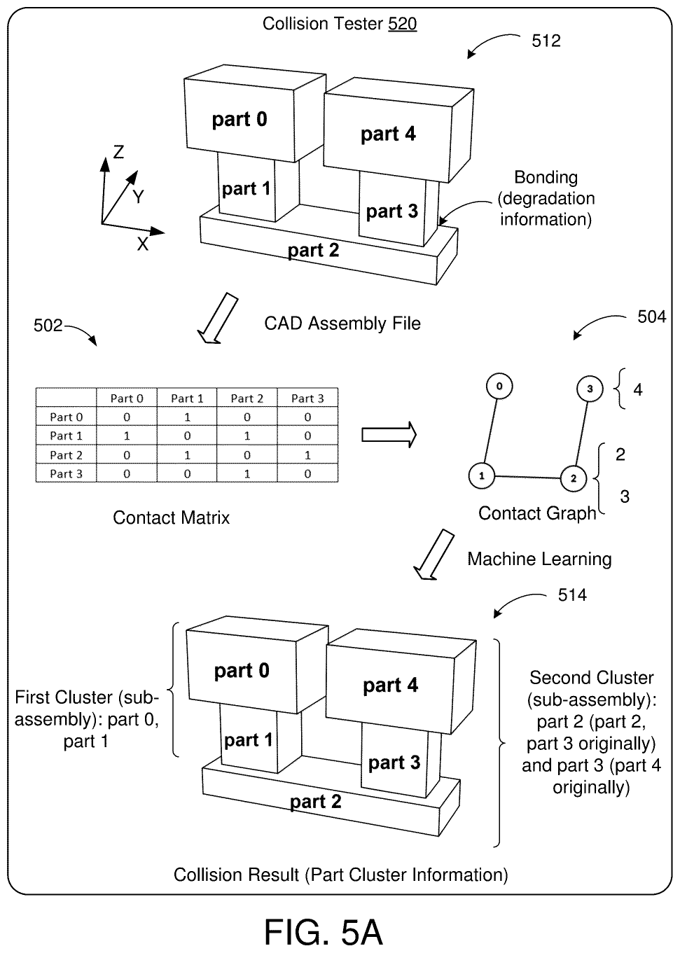

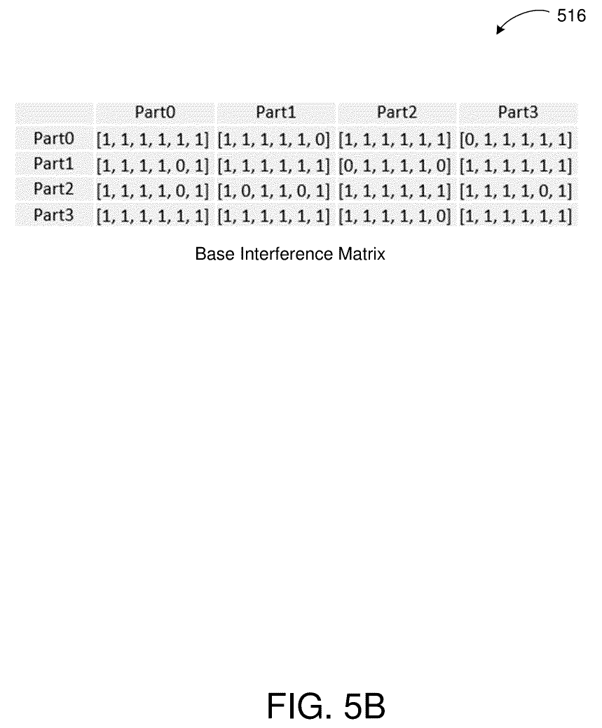

By assigning these attributes to both edges and nodes, the augmenter 424 enables the MDDN to support a range of advanced functionalities. This enriched network allows for the calculation of the total time or cost associated with any given disassembly sequence, supporting detailed cost and time analysis. It also enables optimization modules, such as remanufacturing and repair decision evaluators or robotic trajectory optimization models, to identify the optimal disassembly path for reaching specific components or achieving a desired disassembly depth. Furthermore, high-cost or high-time edges can be identified as bottlenecks in the disassembly process, supporting targeted process improvements. The attribute data also serve as input for generative design algorithms, which can use this information to identify expensive or complex disassembly steps and suggest alternative component orientations, fastening methods, or design changes to reduce disassembly cost or complexity. When component degradation is considered, these edge attributes, especially cost and time, can be dynamically updated in the simulated MDDN to reflect increased difficulty or changes in the nature of operations due to degradation. This will be discussed later in this disclosure (e.g., FIG. 5A).

FIG. 5A illustrates a collision tester 520 configured to generate collision results 514 (e.g., part cluster information) based on CAD assembly file 512 and degradation information 522 in accordance with some implementations of this disclosure.

As discussed above, each of the enhanced simulated MDDNs 520′ is determined based on specific degradation information such as various degradation conditions (e.g., wear, tear, material degradation effects like rust).

In this example, the degradation information 522 defines a simulated degradation scenario where the part 2 and the part 3 are adhesively bonded, rendering them inseparable during disassembly. The collision tester 520 detects this condition and generates a contact matrix 502 reflecting the modified part relationships. As illustrated, the contact matrix 502 reindexes the parts to account for the simulated degradation-part 2 and part 3 are now represented as part 2 and the part 4 is now represented as part 3.

Based on the contact matrix 502, the collision tester 520 generates a contact graph 504. Using the contact graph 504, the collision tester 520 produces collision results 514, which include part cluster information using a machine learning model, such as a community detection model. In this example, the results indicate that a first cluster includes part 0 and part 1, while a second cluster includes part 2 (which now represents both parts 2 and 3) and part 3 (which corresponds to the original part 4).

In some implementations, the collision tester 520 updates part cluster information based on the degradation information.

As illustrated in FIG. 5B, in some implementations, the collision tester 520 is configured to generate interference results 516, such as a base interference matrix based on similar methods described above.

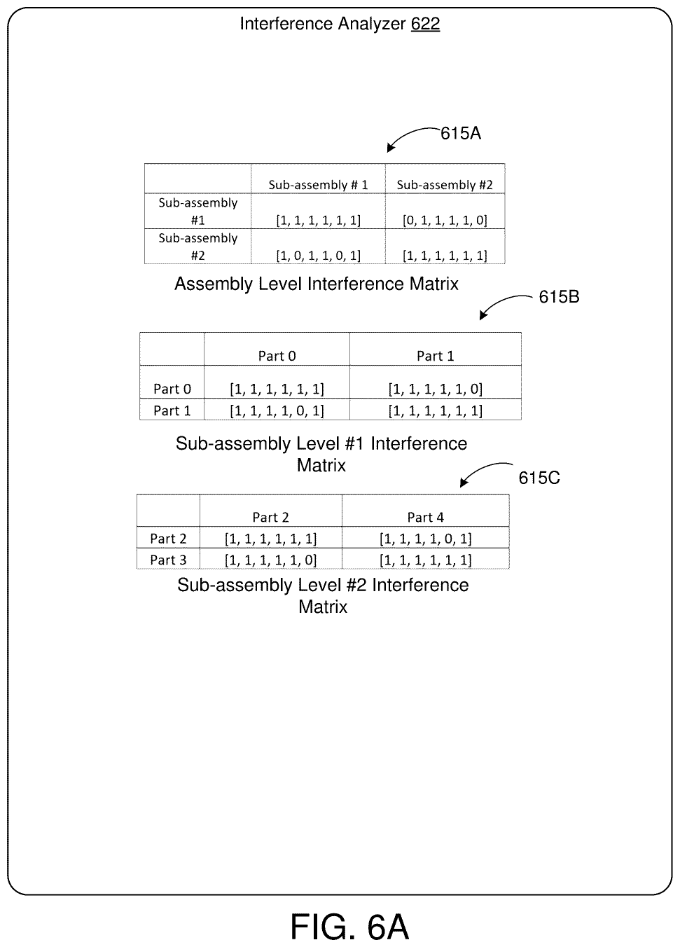

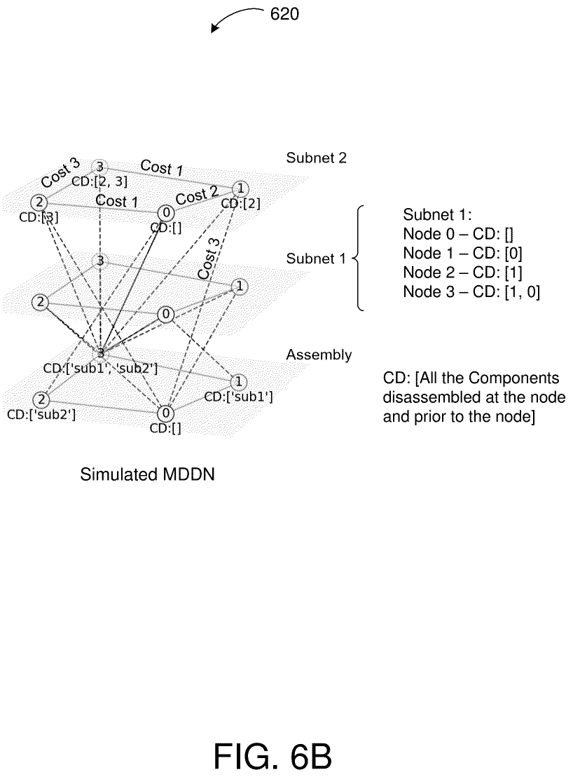

FIG. 6A illustrates an example assembly level interference matrix 615A, one or more sub-assembly matrices (sub-assembly level #1 interference matrix 615B and sub-assembly level interference matrix #2 615C in this example) based on the base interference matrix 516 in FIG. 5B by an interference analyzer 622 in accordance with some implementations of this disclosure.

FIG. 6B illustrates an example simulated MDDN 620 based on the assembly level interference matrix 615A, sub-assembly level #1 interference matrix 615B, and sub-assembly level #2 interference matrix 615C.

As shown, due to the degradation information (part 2 and part 3 bonding together), the simulated MDDN 620 is different from the MDDN in FIG. 3C.

In some implementations, similar to assigning node attributes and edge attributes in FIG. 4, the augmenter assigns various node attributes to each node in the simulated MDDN 620. In some implementations, the augmenter assigns various edge attributes to each edge in the simulated MDDN 620. As a result, the simulated MDDN 620 becomes an enhanced simulated MDDN 620′. In some implementations, multiple enhanced simulated MDDNs 620′ are generated for various degradation conditions.

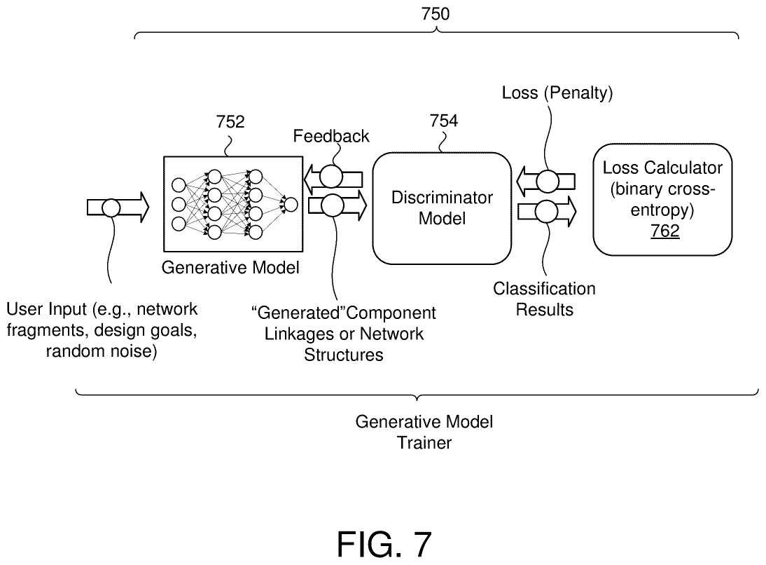

FIG. 7 illustrates a machine learning model 750 including a generator (generative model 752) and a discriminator (discriminator model 754) for the machine learning model 750 in accordance with some implementations of the disclosure.

In some implementations, the model trainer 710 performs trainings (e.g., initial trainings) using knowledge graphs derived from an enhanced base MDDN and one or more enhanced simulated MDDNs.

Once trained, the generative model 752 is configured to understand valid and efficient component linkages, associated disassembly operations, and their costs. This generative model 752 can be used to generate new designs that enhance disassembly by proposing improved linkages or network structures.

The generative model 752, also referred to as “The Creator” or “Forger,” is designed to learn patterns, rules, and structures from existing multilayer direct disassembly networks (MDDNs) and to generate new, synthetic examples. The generative model 752 can produce network fragments, novel component linkages, or partial or complete MDDN structures. The outputs of the generative model 752 are optimized for criteria such as reduced disassembly cost and increased feasibility. For example, the generative model 752 may propose a new method for connecting an M6 screw to a 20 mm hole, based on learned disassembly patterns. The training objective for the generative model 752 is to create outputs that are indistinguishable from valid designs in the training dataset.

The discriminator model 754, also referred to as “The Critic” or “Detective,” is configured to evaluate component linkages or network structures and determine whether they are “real” (derived from valid designs) or “fake” (generated synthetically). This model learns to identify the characteristics of feasible and infeasible disassembly designs, such as recognizing mismatches like an M6 screw in a 20 mm hole. The discriminator model 754 is trained using a database of MDDNs that have been converted into knowledge graphs, which allows it to refine its ability to critique the outputs of the generative model 752. The training objective for the discriminator model 754 is to maximize its accuracy in distinguishing between real and synthetic designs.

In some implementations, the machine learning model 750 is trained through an adversarial process in which the generative and discriminator models 752, 754 compete. Both models are initialized using parameters derived from a database of MDDNs transformed into knowledge graphs. During the generative phase, the generative model 752 produces synthetic disassembly structures, such as network fragments or component linkages. In the discriminative phase, the discriminator model 754 evaluates a mixture of real and synthetic designs, classifying each as either real or fake. The discriminator model updates its parameters to improve classification accuracy, while the generative model 752 updates its parameters based on feedback from the discriminator model 754, refining its outputs to better mimic valid designs. These cycles of generation, discrimination, and parameter updates are repeated iteratively, driving both models toward equilibrium, where the synthetic designs produced by the generative model 752 become indistinguishable from real ones.

As illustrated in FIG. 7, the generative model 752 is configured to receive inputs such as user-provided network fragments, design objectives, or stochastic inputs. In response, the generative model 752 generates candidate component linkages or disassembly network structures. The discriminator model 754 evaluates these outputs, classifying them as either “real: (valid) or “fake” (synthetically generated). In some implementations, a loss calculator 762, employing a binary cross-entropy function, assesses the accuracy of the discriminator model's classifications.

Upon determining an incorrect classification (e.g., mislabeling a synthetic output as valid or vice versa), the loss calculator 762 applies a penalty signal to the discriminator model 754. This penalty drives parameter updates within the discriminator model 754 to enhance its classification accuracy. Concurrently, the discriminator model 754 provides feedback to the generative model 752, identifying deficiencies in the realism or feasibility of its synthetic outputs. This feedback enables the generative model 752 to iteratively adjust its parameters, refining its ability to generate outputs that closely approximate valid disassembly structures.

Through this adversarial training process, the discriminator model 754 progressively improves its ability to distinguish valid designs from synthetic ones, and the generative model 752 progressively improves its ability to generate synthetically valid disassembly structures.

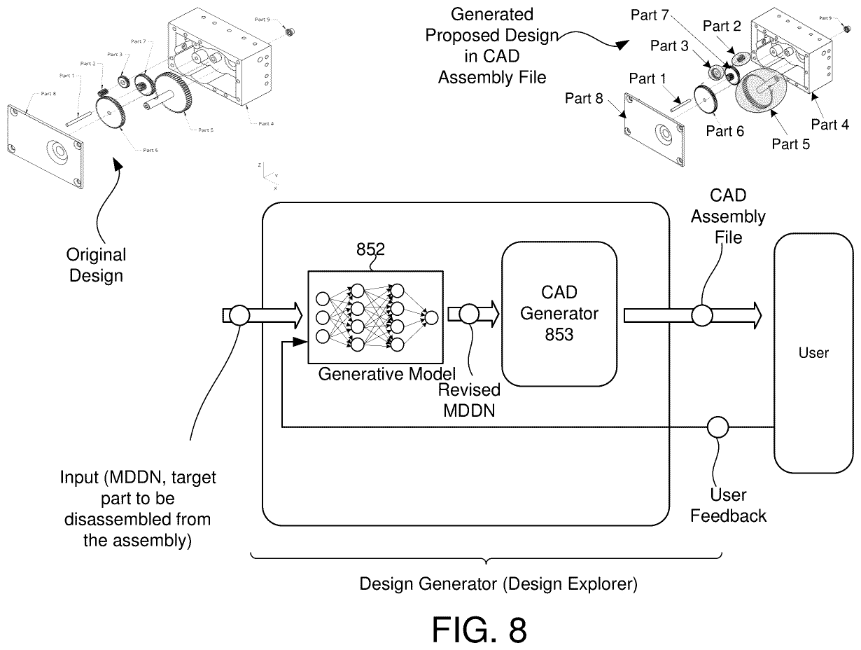

FIG. 8 illustrates a diagram of a design generator for generating CAD assembly files from multilayer direct disassembly networks in accordance with some implementations of the present disclosure.

As shown in FIG. 8, the design generator is configured to receive input data comprising an MDDN and target part to be disassembled from the assembly. The MDDN represents the structural and operational relationships between components in an assembly, while the target part specification identifies specific components that require optimized accessibility for disassembly, maintenance, repair, or recycling operations.

The design generator includes a generative model 852 configured to process the input (e.g., MDDN and target part specifications). In some implementations, the input includes disassembly cost goals (e.g., cost based on disassembly time, cost based on energy requirement for the disassembly, cost based on movements requirement for the disassembly). The generative model 852 comprises a neural network architecture, as illustrated by the interconnected nodes and layers shown in the diagram. The generative model 852 is trained to understand relationships between disassembly network structures and corresponding physical assembly configurations, enabling the generation of a revised MDDN that optimizes for the specified target part accessibility requirements (target part to be disassembled from the assembly is part 3 in this example) while maintaining assembly functionality and design constraints. In some implementations, the generative model 852 is trained as discussed with reference to FIG. 7. In this example, model 852 generated a design (such as the corresponding MDDN) that reconfigures parts 2, 3, and 5 to make disassembling part 3 more efficient and less costly compared to the original design.

The system further comprises a CAD generator 853 configured to convert the revised MDDN output from the generative model 852 into a concrete CAD assembly file. The CAD generator 853 translates the abstract network representation into geometric specifications, component definitions, spatial relationships, assembly constraints, and interface specifications suitable for CAD software applications. The resulting CAD assembly file provides a complete specification for manufacturing, analyzing, or visualizing the optimized assembly design. As illustrated in this example, parts 2, 3, and 5 have been reconfigured to enhance accessibility, making the disassembly of part 3 more efficient.

The design generator incorporates a user interface component that enables presentation of the generated CAD assembly file to a user. The user can review the generated assembly design, evaluate its suitability for the intended application, assess the accessibility of the target components, and analyze the overall design quality and manufacturability. The system enables comprehensive design evaluation through CAD visualization and analysis tools.

The design generator implements a user feedback mechanism that captures user input regarding the generated CAD assembly file. The user feedback may include qualitative assessments, quantitative ratings, specific design modifications, constraint violations, manufacturing concerns, or suggestions for improvement. This feedback provides guidance for refining the generative model 852 to produce designs that better align with user requirements, practical constraints, and real-world applications.

The design generator is configured to incorporate the user feedback into the generative model's parameters, training objectives, or optimization criteria to improve future design generations. The feedback mechanism enables iterative refinement of the generative model 852 through parameter adjustment, training objective modification, or continued training processes that learn from user preferences and domain expertise.

In some implementations, the generative model 852 utilizes advanced machine learning techniques, including neural network architectures trained on databases of existing MDDN structures and corresponding CAD assemblies. The training process enables the generative model 852 to learn patterns of effective design configurations and generate novel assembly designs that incorporate learned design principles while optimizing for specific disassembly objectives and target component accessibility.

The CAD generator 853 incorporates component libraries, standard fastening methods, manufacturing constraints, and design rules to ensure the resulting CAD assembly files represent physically realizable and manufacturable designs. The CAD generator 853 converts abstract network nodes and edges into specific component geometries, interface specifications, and assembly procedures that can be implemented in real-world manufacturing processes.

The design generator enables seamless integration between disassembly planning and CAD design generation, providing a comprehensive solution for creating assemblies that optimize both functional performance and end-of-life disassembly efficiency. The system bridges the gap between abstract disassembly network representations and concrete physical implementations through intelligent automation and user-guided refinement.

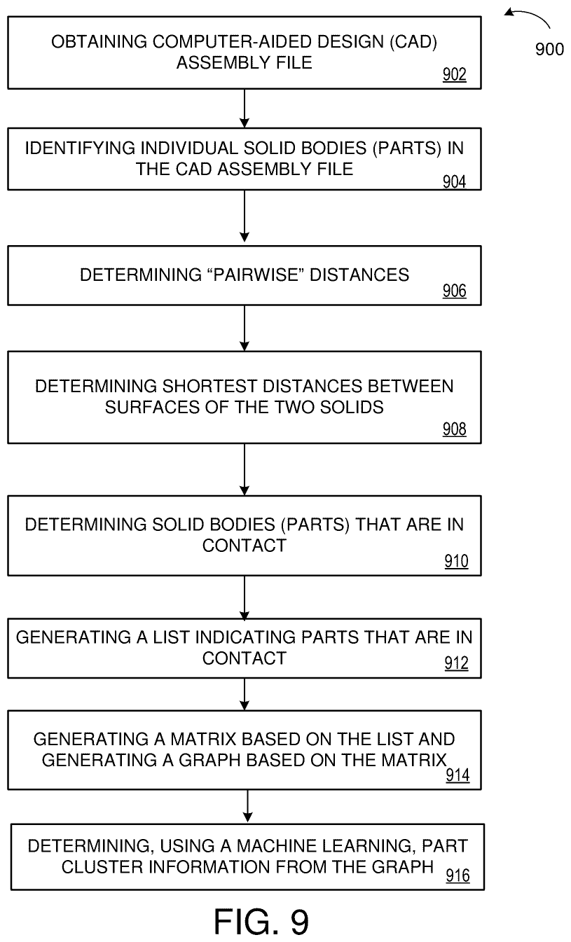

FIG. 9 is a flowchart of an example arrangement of operations for a method 900 for determining (e.g., extracting, generating) part cluster information from a computer-aided design (CAD) assembly file using machine learning in accordance with some implementations of this disclosure. The method 900 may be performed by processing logic that may include data processing hardware (circuitry, dedicated logic, etc.), software (such as is run on a general purpose computer system or a dedicated machine), or a combination of both, which processing logic may be included in any computer system or device. For simplicity of explanation, methods described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter. In addition, those skilled in the art will understand and appreciate that the methods may alternatively be represented as a series of interrelated states via a state diagram or events. Additionally, the methods disclosed in this specification are capable of being stored on an article of manufacture, such as a non-transitory computer-readable medium, to facilitate transporting and transferring such methods to computing devices. The term article of manufacture, as used herein, is intended to encompass a computer program accessible from any computer-readable device or storage media. Although illustrated as discrete blocks, various blocks may be divided into additional blocks, combined into fewer blocks, or eliminated, depending on the desired implementation.

The method 900, at operation 902, includes obtaining, at data processing hardware, a computer-aided design (CAD) assembly file. As discussed above, the CAD assembly file contains geometric and structural information about multiple components that are assembled together to form a complete product or system. The CAD assembly file may be in various formats such as STEP, STP, or STL.

At operation 904, the method 900 includes identifying, by the data processing hardware, individual solid bodies (parts) within an assembly in the CAD assembly file.

At operation 906, the method 900 includes determining, by the data processing hardware, pairwise distances between the identified solid bodies. As discussed above, each solid body represents a distinct component or part within the assembly. The pairwise distance calculation involves computing spatial relationships between every combination of solid bodies. In some implementations, the pairwise distances are calculated between geometric centers of the solid bodies. In other implementations, the distances may be calculated between boundary points or surface features of the solid bodies.

At operation 908, the method 900 includes determining, by the data processing hardware, shortest distances between surfaces of pairs of solid bodies.

At operation 910, the method 900 include determining, by the data processing hardware, which solid bodies (parts) are in contact based on the calculated shortest distances. The shortest distance calculation involves identifying the minimum separation distance between surface meshes or geometric representations of each pair of solid bodies. As discussed above, in some implementations, solid bodies are considered to be in contact when the shortest distance between their surfaces is below a predetermined contact threshold. The contact threshold may be zero for exact contact or a small positive value to account for manufacturing tolerances or computational precision limitations.

At operation 912, the method 900 includes generating, by the data processing hardware, a contact list indicating which parts are in contact with each other. The contact list provides a structured representation of the contact relationships identified in the previous operation.

At operation 914, the method 900 includes generating, by the data processing hardware, a matrix based on the contact list and generating, by the data processing hardware, a graph structure (e.g., contact graph) based on the matrix. In some implementations, the contact list is formatted as a matrix where rows and columns represent individual parts. In some implementations, the graph structure enables network analysis of the assembly. As discussed above, the graph representation treats each part as a node and each contact relationship as an edge connecting the corresponding nodes. In some implementations, the graph may be weighted based on contact strength, surface area of contact, or other geometric properties.

At operation 916, the method 900 includes determining, by the data processing hardware, part cluster information from the graph using machine learning algorithms. In some implementations, the machine learning system analyzes the graph structure to identify meaningful clusters of parts based on their connectivity patterns and spatial relationships. In some implementations, the machine learning algorithms include clustering techniques such as k-means clustering, hierarchical clustering, or graph-based clustering algorithms. The clustering process groups parts that exhibit similar connectivity patterns or spatial proximity, enabling identification of sub-assemblies or functional groupings within the overall assembly.

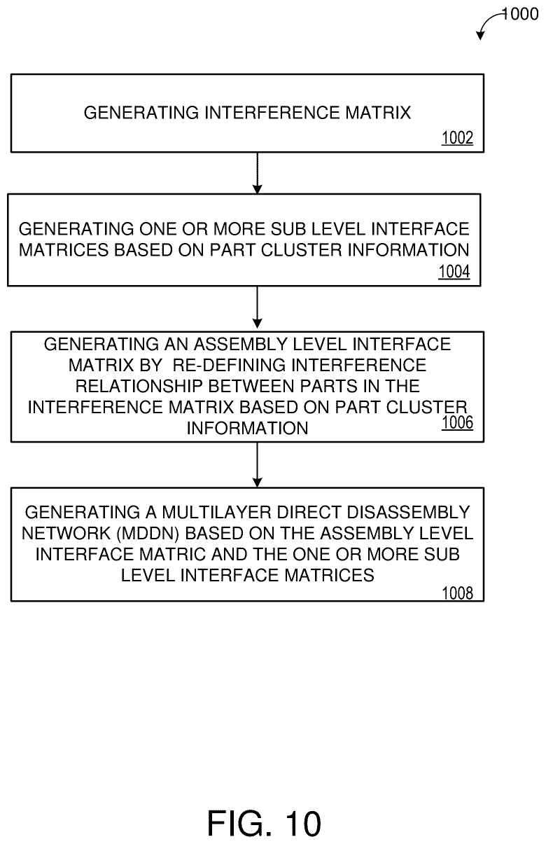

FIG. 10 illustrates a flowchart of process 1000 for generating a multilayer direct disassembly network (MDDN) using base interference matrix analysis in accordance with some implementations of the present disclosure. The method 1000 may be performed by processing logic that may include data processing hardware (circuitry, dedicated logic, etc.), software (such as is run on a general purpose computer system or a dedicated machine), or a combination of both, which processing logic may be included in any computer system or device. For simplicity of explanation, methods described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter. In addition, those skilled in the art will understand and appreciate that the methods may alternatively be represented as a series of interrelated states via a state diagram or events. Additionally, the methods disclosed in this specification are capable of being stored on an article of manufacture, such as a non-transitory computer-readable medium, to facilitate transporting and transferring such methods to computing devices. The term article of manufacture, as used herein, is intended to encompass a computer program accessible from any computer-readable device or storage media. Although illustrated as discrete blocks, various blocks may be divided into additional blocks, combined into fewer blocks, or eliminated, depending on the desired implementation.

The process 1000, at operation 1002, includes generating, at data processing hardware, a base interference matrix. The base interference matrix represents spatial and geometric interference relationships between individual parts in a computer-aided design (CAD) assembly. The base interference matrix provides a foundational representation of how parts interact and constrain each other's movement during potential disassembly operations. In some implementations, the interference matrix is generated by analyzing geometric collision data, contact surfaces, and spatial proximity relationships between parts in the assembly.

At operation 1004, the process 1000 includes generating, by the data processing hardware, one or more sub-level interface matrices based on part cluster information. The part cluster information identifies groupings of parts that function as sub-assemblies or logical units within the overall assembly. Each sub-level interface matrix represents interference relationships within a specific part cluster, enabling focused analysis of disassembly operations at the sub-assembly level. The sub-level interface matrices are derived by extracting relevant portions of the base interference matrix that correspond to parts within each identified cluster.

At operation 1006, the process 1000 includes generating, by the data processing hardware, an assembly-level interface matrix by redefining interference relationships between parts in the interference matrix based on the part cluster information. The assembly-level interface matrix provides a higher-level view of the assembly by treating entire part clusters as single entities. This redefining process involves consolidating interference relationships between individual parts into cluster-level relationships, thereby simplifying the representation while preserving essential disassembly constraints. The assembly-level interface matrix enables efficient analysis of disassembly sequences that involve removing entire sub-assemblies as units.

At operation 1008, the process 1000 includes generating, by the data processing hardware, a multilayer direct disassembly network (MDDN) based on the assembly-level interface matrix and the one or more sub-level interface matrices. The MDDN integrates multiple levels of analysis, combining assembly-level disassembly planning with detailed sub-assembly-level operations. The multilayer structure enables comprehensive disassembly planning that can optimize sequences at both coarse and fine granularities. The MDDN represents disassembly operations as nodes and edges, where nodes represent disassembly states and edges represent feasible disassembly transitions.

In some implementations, the MDDN generation process involves creating interconnected network layers, where the assembly-level layer manages high-level disassembly decisions and sub-level layers manage detailed operations within specific part clusters. The multilayer structure enables hierarchical optimization of disassembly sequences, supporting both rapid coarse-level planning and detailed fine-level execution planning.

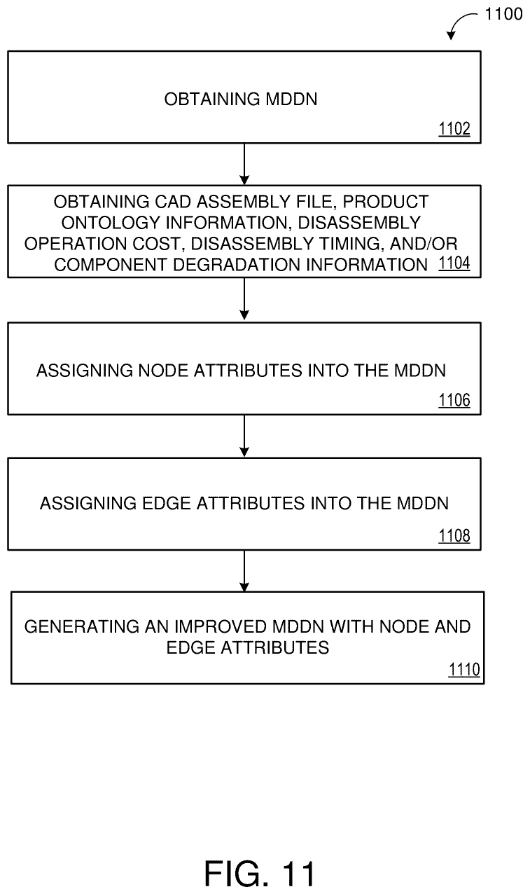

FIG. 11 illustrates a flowchart of an example arrangement of operations for a method 1100 for generating an improved multilayer direct disassembly network (MDDN) with node and edge attributes in accordance with some implementations of the present disclosure. The method 1100 may be performed by processing logic that may include data processing hardware (circuitry, dedicated logic, etc.), software (such as is run on a general purpose computer system or a dedicated machine), or a combination of both, which processing logic may be included in any computer system or device. For simplicity of explanation, methods described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter. In addition, those skilled in the art will understand and appreciate that the methods may alternatively be represented as a series of interrelated states via a state diagram or events. Additionally, the methods disclosed in this specification are capable of being stored on an article of manufacture, such as a non-transitory computer-readable medium, to facilitate transporting and transferring such methods to computing devices. The term article of manufacture, as used herein, is intended to encompass a computer program accessible from any computer-readable device or storage media. Although illustrated as discrete blocks, various blocks may be divided into additional blocks, combined into fewer blocks, or eliminated, depending on the desired implementation.

At operation 1102, the method 1100 includes obtaining a base MDDN (e.g., initial MDDN). The MDDN may be generated from a CAD assembly file or other digital product structure data and represents the relationships and possible disassembly paths among components in an assembly.

At operation 1104, the method 1100 includes obtaining, at data processing hardware, one or more of a CAD assembly file, product ontology information, disassembly operation cost, disassembly timing, and/or component degradation information. The CAD assembly file provides geometric and structural information about the assembly. Product ontology information includes definitions of component types, interfaces, and standard disassembly operations. Disassembly operation cost and timing data quantify the resources required for each disassembly step. Component degradation information reflects the condition or wear state of each component, which may affect disassembly feasibility and cost.

At operation 1106, the method 1100 includes assigning, by data processing hardware, node attributes into the MDDN. Node attributes may include, but are not limited to, component type, disassembly direction, degradation state, lifespan, physical dimensions, and material properties. These attributes provide detailed context for each node, representing a component or sub-assembly in the network.

At operation 1108, the method 1100 includes assigning, by data processing hardware, edge attributes into the MDDN. Edge attributes may include, but are not limited to, the type of disassembly operation required, estimated time and cost for the operation, and any process-specific constraints. These edge attributes characterize the transitions or actions necessary to move from one disassembly state to another within the MDDN.

At operation 1110, the method 1100 includes generating, by data processing hardware, an improved MDDN with the assigned node and edge attributes. The resulting enhanced MDDN provides a comprehensive, information-rich representation of the assembly and its disassembly process, enabling advanced simulation, optimization, and automated decision-making for disassembly planning, remanufacturing, and product lifecycle management. Furthermore, the enhanced MDDN can be utilized to develop product designs that specifically consider a target part intended for disassembly.

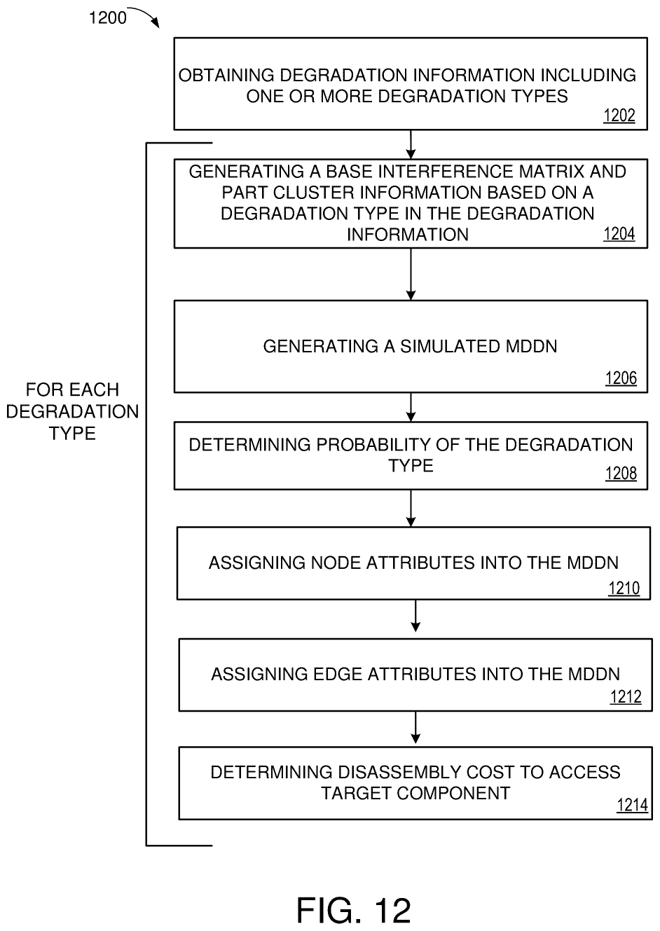

FIG. 12 illustrates a flowchart of an example arrangement of operations for a method 1200 for generating an enhanced simulated multilayer direct disassembly network (MDDN) in accordance with some implementations of the present disclosure. The method 1200 may be performed by processing logic that may include data processing hardware (circuitry, dedicated logic, etc.), software (such as is run on a general purpose computer system or a dedicated machine), or a combination of both, which processing logic may be included in any computer system or device. For simplicity of explanation, methods described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter. In addition, those skilled in the art will understand and appreciate that the methods may alternatively be represented as a series of interrelated states via a state diagram or events. Additionally, the methods disclosed in this specification are capable of being stored on an article of manufacture, such as a non-transitory computer-readable medium, to facilitate transporting and transferring such methods to computing devices. The term article of manufacture, as used herein, is intended to encompass a computer program accessible from any computer-readable device or storage media. Although illustrated as discrete blocks, various blocks may be divided into additional blocks, combined into fewer blocks, or eliminated, depending on the desired implementation.

The method 1200, at operation 1202, includes obtaining, at data processing hardware, degradation information including one or more degradation types. The degradation information specifies various forms of component degradation that may affect disassembly operations, such as corrosion, wear, material brittleness, adhesive bonding due to environmental exposure, mechanical deformation, or component fusion. In some implementations, the degradation information includes specific degradation conditions such as rust formation, material fatigue, thermal degradation, or chemical deterioration that alter component separability and disassembly requirements.

At operation 1204, the method 1200 includes generating, by the data processing hardware, a base interference matrix and part cluster information based on a degradation type specified in the degradation information. The degradation type affects both the base interference matrix and the part cluster information, resulting in modifications that reflect the impact of the specified degradation. For example, the part cluster information identifies how degradation affects component groupings and sub-assembly relationships.

At operation 1206, the method 1200 includes generating, by the data processing hardware, a simulated multilayer direct disassembly network (MDDN) for the degradation type. The simulated MDDN incorporates the effects of specific degradation conditions on disassembly operations by modifying interference relationships, disassembly constraints, and operational feasibility. The simulated MDDN represents a unique scenario reflecting how particular degradation conditions impact the overall disassembly process.

At operation 1208, the method 1200 includes determining, by the data processing hardware, the probability of the degradation type under consideration. The probability determination process evaluates the likelihood of specific degradation condition occurring based on factors such as component age, operating environment, material properties, usage history, and exposure conditions. In some implementations, the probability calculation incorporates historical degradation data, environmental exposure models, accelerated aging test results, or predictive degradation algorithms to estimate degradation likelihood accurately.

At operation 1210, the method 1200 includes assigning, by the data processing hardware, node attributes into the simulated MDDN. In some implementations, the node attributes incorporate degradation-related information such as component degradation state, degradation probability, expected remaining lifespan, degradation-modified material properties, structural integrity, and accessibility constraints. The node attributes may also include component type, disassembly direction, physical dimensions, material composition, and other relevant characteristics that may be affected by degradation conditions.

At operation 1212, the method 1200 includes assigning, by the data processing hardware, edge attributes into the MDDN. The edge attributes incorporate degradation effects on disassembly operations, including modified operation types, adjusted time requirements, increased costs, specialized tool requirements, and alternative disassembly methods necessitated by degradation conditions. The edge attributes may also include safety considerations, risk assessments, and operational constraints imposed by degradation-induced changes in component properties or accessibility.

At operation 1214, the method 1200 includes determining, by the data processing hardware, disassembly cost to access a target component. The cost determination process calculates the total resource requirements for disassembling the assembly to reach a specific target component, accounting for degradation effects on operation costs, time requirements, tool needs, and feasibility constraints. In some implementations, the cost calculation incorporates probabilistic analysis to provide expected cost ranges, confidence intervals, and risk assessments based on degradation probability distributions across multiple scenarios.

In some implementations, a simulated MDDN can be generated by iteratively performing the above operations for each degradation type specified in the degradation information.

The resulting enhanced simulated MDDN provides a comprehensive framework for robust disassembly planning that accounts for uncertainty and variability in component conditions. This enables more accurate cost estimation, risk assessment, and decision-making for end-of-life product management, remanufacturing operations, and component recovery strategies. Furthermore, the enhanced simulated MDDN can be utilized to develop product designs that specifically consider a target part intended for disassembly.

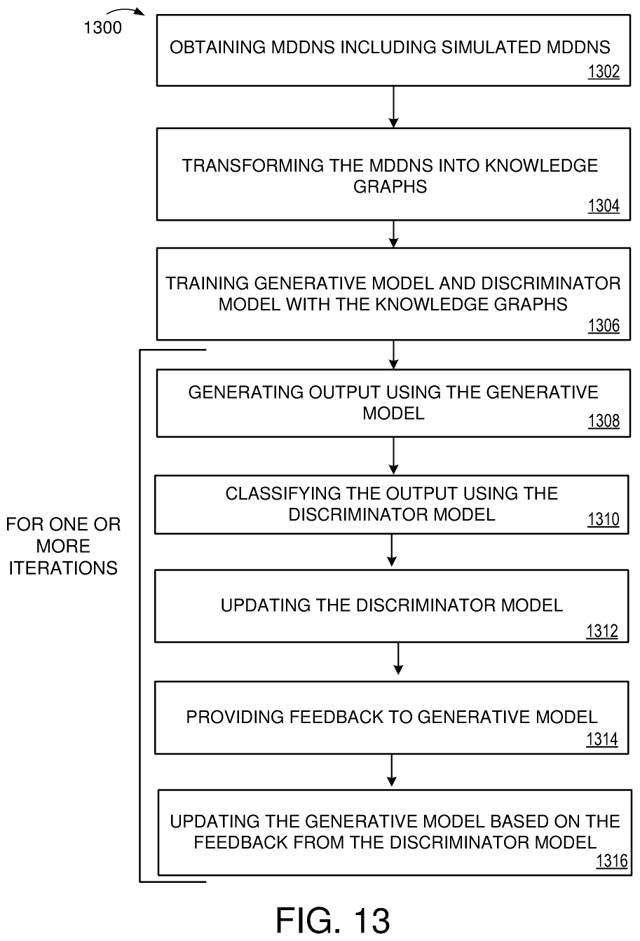

FIG. 13 illustrates a flowchart of an example arrangement of operations for a method 1300 for training a model for disassembly network generation using adversarial learning in accordance with some implementations of the present disclosure. The method 1300 may be performed by processing logic that may include data processing hardware (circuitry, dedicated logic, etc.), software (such as is run on a general purpose computer system or a dedicated machine), or a combination of both, which processing logic may be included in any computer system or device. For simplicity of explanation, methods described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter. In addition, those skilled in the art will understand and appreciate that the methods may alternatively be represented as a series of interrelated states via a state diagram or events. Additionally, the methods disclosed in this specification are capable of being stored on an article of manufacture, such as a non-transitory computer-readable medium, to facilitate transporting and transferring such methods to computing devices. The term article of manufacture, as used herein, is intended to encompass a computer program accessible from any computer-readable device or storage media. Although illustrated as discrete blocks, various blocks may be divided into additional blocks, combined into fewer blocks, or eliminated, depending on the desired implementation.

The method 1300, at operation 1302, includes obtaining, at data processing hardware, multilayer direct disassembly networks (MDDNs) including simulated MDDNs and base MDDN. The MDDNs represent disassembly sequences and operations for various assemblies, including both real-world disassembly networks derived from existing products and simulated networks that incorporate degradation scenarios, alternative disassembly strategies, or hypothetical design configurations. As discussed above, the collection of MDDNs provides a comprehensive training dataset that captures diverse disassembly patterns, constraints, and optimization criteria.

At operation 1304, the method 1300 includes transforming, by the data processing hardware, the MDDNs into knowledge graphs. The transformation process converts the network structure of MDDNs into graph-based representations that are suitable for machine learning processing. The knowledge graphs preserve the essential relationships, constraints, and attributes of the original MDDNs while providing a standardized format for model training. In some implementations, the knowledge graphs incorporate node attributes representing component properties and edge attributes representing disassembly operations, costs, and constraints.

At operation 1306, the method 1300 includes training, by the data processing hardware, a generative model and a discriminator model with the knowledge graphs. The generative model is configured to learn patterns from the knowledge graphs and generate new disassembly network structures. The discriminator model is configured to evaluate the quality and feasibility of generated networks by distinguishing between real networks from the training data and synthetic networks produced by the generative model. As discussed above, this adversarial training approach drives both models to improve through competitive optimization.

At operation 1308, the method 1300 includes generating, by the data processing hardware, output using the generative model. The generative model produces synthetic disassembly network structures, component linkages, or network fragments based on learned patterns from the training data. The generated outputs represent novel disassembly configurations that incorporate learned design principles and optimization criteria while potentially exploring new design spaces not present in the original training data.

At operation 1310, the method 1300 includes classifying, by the data processing hardware, the output using the discriminator model. The discriminator model evaluates the generated outputs and classifies them as either realistic and feasible or synthetic and potentially problematic. This classification process provides feedback on the quality of the generative model's outputs and identifies areas for improvement in the generated disassembly structures.

At operation 1312, the method 1300 includes updating, by the data processing hardware, the discriminator model based on its classification performance. The discriminator model's parameters are adjusted to improve its ability to distinguish between real and generated disassembly networks. The updating process enhances the discriminator model's capability to identify subtle differences between valid and invalid disassembly configurations, providing more accurate feedback for the generative model training process.

At operation 1314, the method 1300 includes providing, by the data processing hardware, feedback to the generative model based on the discriminator model's classification results. The feedback mechanism communicates the discriminator model's assessment of the generated outputs, indicating which aspects of the generated networks are realistic and which require improvement. This feedback drives the competitive aspect of the adversarial training process.

At operation 1316, the method 1300 includes updating, by the data processing hardware, the generative model based on the feedback from the discriminator model. The generative model's parameters are adjusted to produce outputs that are more likely to be classified as realistic and feasible by the discriminator model. In some implementations, operations 1308 through 1316 are repeated for one or more iterations until the models reach a desired level of performance, where the generative model produces high-quality disassembly networks that are difficult for the discriminator model to distinguish from real networks.

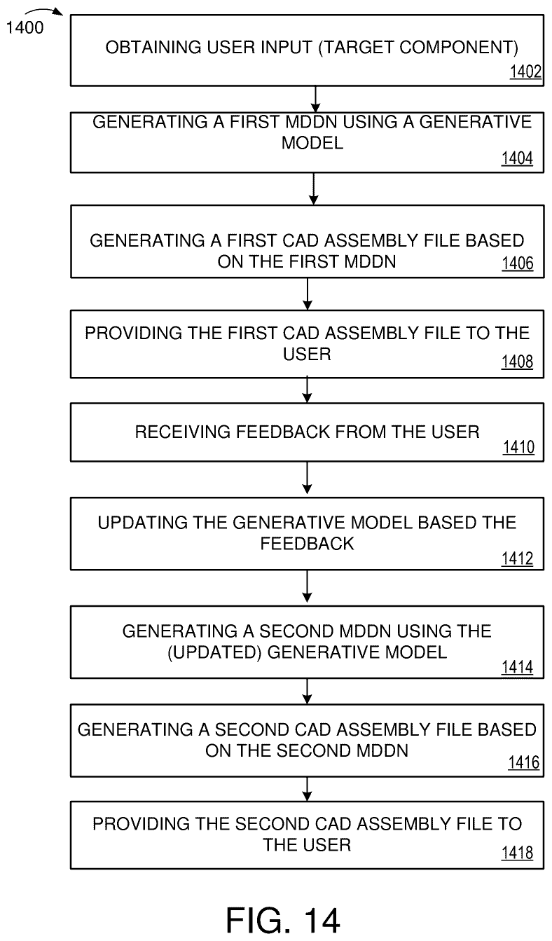

FIG. 14 illustrates a flowchart of an example arrangement of operations for a method 1400 for iterative generative design of CAD assemblies using multilayer direct disassembly networks with user feedback integration in accordance with some implementations of the present disclosure. The method 1400 may be performed by processing logic that may include data processing hardware (circuitry, dedicated logic, etc.), software (such as is run on a general purpose computer system or a dedicated machine), or a combination of both, which processing logic may be included in any computer system or device. For simplicity of explanation, methods described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter. In addition, those skilled in the art will understand and appreciate that the methods may alternatively be represented as a series of interrelated states via a state diagram or events. Additionally, the methods disclosed in this specification are capable of being stored on an article of manufacture, such as a non-transitory computer-readable medium, to facilitate transporting and transferring such methods to computing devices. The term article of manufacture, as used herein, is intended to encompass a computer program accessible from any computer-readable device or storage media. Although illustrated as discrete blocks, various blocks may be divided into additional blocks, combined into fewer blocks, or eliminated, depending on the desired implementation.

The method 1400, at operation 1402, includes obtaining, at data processing hardware, user input specifying a target component. The user input defines specific components or sub-assemblies that are of particular interest for disassembly operations, such as components requiring maintenance, repair, or recycling. The target component specification provides guidance for the generative model to optimize disassembly sequences and assembly structures that facilitate efficient access to the specified components. In some implementations, the user input may include multiple target components, priority rankings, or specific disassembly constraints and requirements.

At operation 1404, the method 1400 includes generating, by the data processing hardware, a first multilayer direct disassembly network (MDDN) using a generative model. The generative model produces a synthetic MDDN that incorporates learned patterns from training data while optimizing for the specified target component accessibility. The first MDDN represents disassembly sequences, component relationships, and operational constraints that facilitate efficient access to the target component. As discussed above, the generative model leverages adversarial training to produce realistic and feasible disassembly network structures.

At operation 1406, the method 1400 includes generating, by the data processing hardware, a first CAD assembly file based on the first MDDN. The conversion process translates the abstract network representation of the MDDN into concrete geometric and structural specifications suitable for CAD representation. The resulting CAD assembly file includes component geometries, spatial relationships, assembly constraints, and interface specifications that correspond to the disassembly network structure. In some implementations, the CAD generation process incorporates component libraries, standard fastening methods, and manufacturing constraints to ensure the resulting assembly is physically realizable.

At operation 1408, the method 1400 includes providing, by the data processing hardware, the first CAD assembly file to the user. In some implementations, the CAD assembly file is presented through appropriate user interfaces, such as CAD visualization software, web-based viewers, or specialized design review applications. The presentation enables the user to examine the generated assembly design, evaluate its suitability for the intended application, and assess the accessibility of the target component within the proposed assembly structure.

At operation 1410, the method 1400 includes receiving, by the data processing hardware, feedback from the user regarding the first CAD assembly file. The user feedback may include qualitative assessments, quantitative ratings, specific design modifications, constraint violations, or suggestions for improvement. The feedback mechanism captures user preferences, domain expertise, and practical considerations that may not be fully captured in the original training data. As discussed above, the feedback provides guidance for refining the generative model to produce designs that better align with user requirements and real-world constraints. For example, through the feedback process, the user can request a new design that further reduces the disassembly cost of the target part.

At operation 1412, the method 1400 includes updating, by the data processing hardware, the generative model based on the received feedback. The model updating process incorporates the user feedback into the generative model's parameters or training objectives to improve future design generations. The updating mechanism may involve fine-tuning model weights, adjusting optimization objectives, or incorporating feedback data into continued training processes. The updated generative model reflects learned user preferences and incorporates domain-specific knowledge provided through the feedback mechanism.

At operation 1414, the method 1400 includes generating, by the data processing hardware, a second MDDN using the updated generative model. The updated model produces an improved disassembly network that incorporates lessons learned from the user feedback. The second MDDN represents a refined design iteration that addresses user concerns, incorporates suggested improvements, and better optimizes for the specified target component accessibility requirements.

At operation 1416, the method 1400 includes generating, by the data processing hardware, a second CAD assembly file based on the second MDDN. The second CAD assembly file represents an improved design iteration that incorporates user feedback and demonstrates enhanced performance relative to the first design iteration. The improved assembly design maintains the optimization objectives for target component accessibility while addressing user concerns and preferences identified in the feedback process.

At operation 1418, the method 1400 includes providing, by the data processing hardware, the second CAD assembly file to the user. The iterative process enables continuous design refinement through successive feedback loops, allowing the system to progressively improve design quality and user satisfaction. As discussed above, this iterative approach can be repeated multiple times to achieve desired design performance and user acceptance levels.

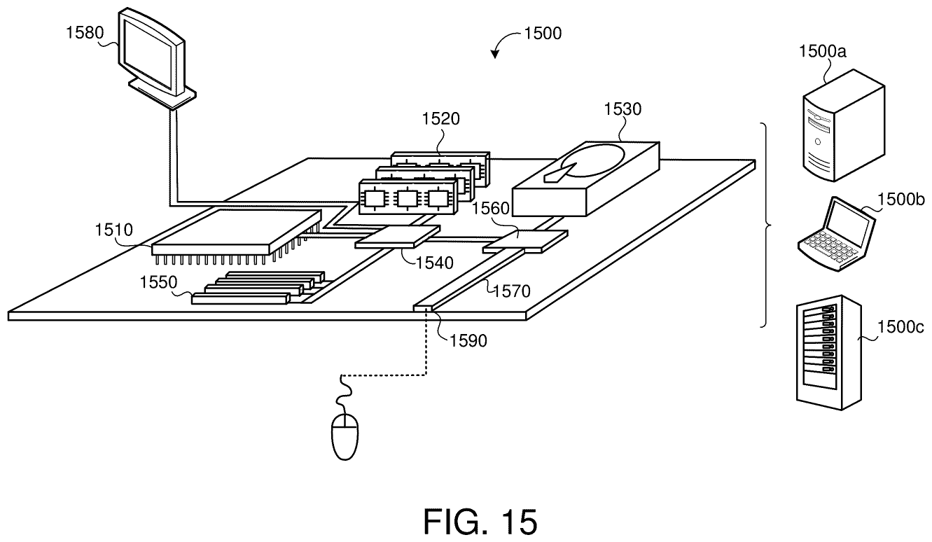

FIG. 15 is schematic view of an example computing device 1500 that may be used to implement the systems and methods described in this document. The computing device 1500 is intended to represent various forms of digital computers, such as laptops, desktops, workstations, personal digital assistants, servers, blade servers, mainframes, and other appropriate computers. The components shown here, their connections and relationships, and their functions, are meant to be exemplary only, and are not meant to limit implementations of the inventions described and/or claimed in this document.

The computing device 1500 includes a processor 1510, memory 1520, a storage device 1530, a high-speed interface/controller 1540 connecting to the memory 1520 and high-speed expansion ports 1550, and a low speed interface/controller 1560 connecting to a low speed bus 1570 and a storage device 1530. Each of the components 1510, 1520, 1530, 1540, 1550, and 1560, are interconnected using various busses, and may be mounted on a common motherboard or in other manners as appropriate. The processor 1510 can process instructions for execution within the computing device 1500, including instructions stored in the memory 1520 or on the storage device 1530 to display graphical information for a graphical user interface (GUI) on an external input/output device, such as display 1580 coupled to high speed interface 1540. In other implementations, multiple processors and/or multiple buses may be used, as appropriate, along with multiple memories and types of memory. Also, multiple computing devices 1500 may be connected, with each device providing portions of the necessary operations (e.g., as a server bank, a group of blade servers, or a multi-processor system).

The memory 1520 stores information non-transitorily within the computing device 1500. The memory 1520 may be a computer-readable medium, a volatile memory unit(s), or non-volatile memory unit(s). The non-transitory memory 1520 may be physical devices used to store programs (e.g., sequences of instructions) or data (e.g., program state information) on a temporary or permanent basis for use by the computing device 1500. Examples of non-volatile memory include, but are not limited to, flash memory and read-only memory (ROM)/programmable read-only memory (PROM)/erasable programmable read-only memory (EPROM)/electronically erasable programmable read-only memory (EEPROM) (e.g., typically used for firmware, such as boot programs). Examples of volatile memory include, but are not limited to, random access memory (RAM), dynamic random access memory (DRAM), static random access memory (SRAM), phase change memory (PCM) as well as disks or tapes.

The storage device 1530 is capable of providing mass storage for the computing device 1500. In some implementations, the storage device 1530 is a computer-readable medium. In various different implementations, the storage device 1530 may be a floppy disk device, a hard disk device, an optical disk device, or a tape device, a flash memory or other similar solid state memory device, or an array of devices, including devices in a storage area network or other configurations. In additional implementations, a computer program product is tangibly embodied in an information carrier. The computer program product contains instructions that, when executed, perform one or more methods, such as those described above. The information carrier is a computer- or machine-readable medium, such as the memory 1520, the storage device 1530, or memory on processor 1510.

The high speed controller 1540 manages bandwidth-intensive operations for the computing device 1500, while the low speed controller 1560 manages lower bandwidth-intensive operations. Such allocation of duties is exemplary only. In some implementations, the high-speed controller 1540 is coupled to the memory 1520, the display 1580 (e.g., through a graphics processor or accelerator), and to the high-speed expansion ports 1550, which may accept various expansion cards (not shown). In some implementations, the low-speed controller 1560 is coupled to the storage device 1530 and a low-speed expansion port 1590. The low-speed expansion port 1590, which may include various communication ports (e.g., USB, Bluetooth, Ethernet, wireless Ethernet), may be coupled to one or more input/output devices, such as a keyboard, a pointing device, a scanner, or a networking device such as a switch or router, e.g., through a network adapter.

The computing device 1500 may be implemented in a number of different forms, as shown in the figure. For example, it may be implemented as a standard server 1500a or multiple times in a group of such servers 1500a, as a laptop computer 1500b, or as part of a rack server system 1500c.

Various implementations of the systems and techniques described herein can be realized in digital electronic and/or optical circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

A software application (i.e., a software resource) may refer to computer software that causes a computing device to perform a task. In some examples, a software application may be referred to as an “application,” an “app,” or a “program.” Example applications include, but are not limited to, system diagnostic applications, system management applications, system maintenance applications, word processing applications, spreadsheet applications, messaging applications, media streaming applications, social networking applications, and gaming applications.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” and “computer-readable medium” refer to any computer program product, non-transitory computer readable medium, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

The processes and logic flows described in this specification can be performed by one or more programmable processors, also referred to as data processing hardware, executing one or more computer programs to perform functions by operating on input data and generating output. The processes and logic flows can also be performed by special purpose logic circuitry, e.g., an FPGA (field programmable gate array) or an ASIC (application specific integrated circuit). Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, one or more aspects of the disclosure can be implemented on a computer having a display device, e.g., a CRT (cathode ray tube), LCD (liquid crystal display) monitor, or touch screen for displaying information to the user and optionally a keyboard and a pointing device, e.g., a mouse or a trackball, by which the user can provide input to the computer. Other kinds of devices can be used to provide interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Various implementations of the systems and techniques described herein can be realized in digital electronic and/or optical circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

A software application (i.e., a software resource) may refer to computer software that causes a computing device to perform a task. In some examples, a software application may be referred to as an “application,” an “app,” or a “program.” Example applications include, but are not limited to, system diagnostic applications, system management applications, system maintenance applications, word processing applications, spreadsheet applications, messaging applications, media streaming applications, social networking applications, and gaming applications.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” and “computer-readable medium” refer to any computer program product, non-transitory computer readable medium, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

The processes and logic flows described in this specification can be performed by one or more programmable processors, also referred to as data processing hardware, executing one or more computer programs to perform functions by operating on input data and generating output. The processes and logic flows can also be performed by special purpose logic circuitry, e.g., an FPGA (field programmable gate array) or an ASIC (application specific integrated circuit). Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, one or more aspects of the disclosure can be implemented on a computer having a display device, e.g., a CRT (cathode ray tube), LCD (liquid crystal display) monitor, or touch screen for displaying information to the user and optionally a keyboard and a pointing device, e.g., a mouse or a trackball, by which the user can provide input to the computer. Other kinds of devices can be used to provide interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

A number of implementations have been described. Nevertheless, it will be understood that various modifications may be made without departing from the spirit and scope of the disclosure. Accordingly, other implementations are within the scope of the following claims.

What is claimed is:

1. A method for training a machine learning model, the method comprising:
obtaining a plurality of enhanced multilayer direct disassembly networks (MDDNs);
transforming the plurality of enhanced MDDNs into corresponding knowledge graphs; and
training the machine learning model using the corresponding knowledge graphs.

2. The method of claim 1, wherein training the machine learning model comprises:
training a generative component of the machine learning model using the knowledge graphs; and
training a discriminator component of the machine learning model using the knowledge graphs.

3. The method of claim 2, further comprising:
generating a synthetic disassembly network structure using the generative component; and
classifying the synthetic disassembly network structure using the discriminator component.

4. The method of claim 3, further comprising:
in response to determining that the discriminator component classified the synthetic disassembly network structure as synthetic, updating one or more parameters of the generative component based on feedback from the discriminator component.

5. The method of claim 3, further comprising:
determining whether the discriminator component misclassified the synthetic disassembly network structure; and
in response to determining that the synthetic disassembly network structure was misclassified, updating one or more parameters of the discriminator component based on feedback from a loss evaluation module.

6. The method of claim 1, wherein the plurality of enhanced multilayer direct disassembly networks (MDDNs) includes an enhanced base MDDN generated by:
obtaining a computer-aided design (CAD) assembly file representing an assembly of components;
determining pairs of components in contact by calculating surface-to-surface distances below a predefined threshold;
generating a contact matrix wherein rows and columns correspond to components, and matrix entries indicate contact relationships;
converting the contact matrix into a contact graph comprising nodes representing components and edges representing contact relationships; and
generating a collision result comprising part cluster information by applying a machine learning clustering algorithm to the contact graph.

7. The method of claim 1, wherein the plurality of enhanced multilayer direct disassembly networks (MDDNs) includes a first enhanced simulated MDDN generated by:
obtaining a computer-aided design (CAD) assembly file representing an assembly of components;
determining pairs of components in contact by calculating surface-to-surface distances below a predefined threshold;
determining non-separable component pairs based on first degradation data;
generating a first contact matrix wherein rows and columns correspond to components, and matrix entries indicate contact relationships;
converting the first contact matrix into a first contact graph comprising nodes representing components and edges representing contact relationships; and
generating a first collision result comprising part cluster information by applying a machine learning clustering algorithm to the first contact graph,
wherein non-separable component pairs are represented as a single component in the first contact matrix.

8. The method of claim 7, wherein the plurality of enhanced multilayer direct disassembly networks (MDDNs) includes a second enhanced simulated MDDN generated by:
obtaining the computer-aided design (CAD) assembly file representing an assembly of components;
determining pairs of components in contact by calculating surface-to-surface distances below a predefined threshold;
determining non-separable component pairs based on second degradation data, wherein the second degradation data is different from the first degradation data;
generating a second contact matrix wherein rows and columns correspond to components, and matrix entries indicate contact relationships;
converting the second contact matrix into a second contact graph comprising nodes representing components and edges representing contact relationships; and
generating a second collision result comprising part cluster information by applying a machine learning clustering algorithm to the second contact graph,
wherein non-separable component pairs are represented as a single component in the second contact matrix.

9. A system comprising:
data processing hardware; and
memory hardware in communication with the data processing hardware, the memory hardware storing instructions that when executed on the data processing hardware cause the data processing hardware to perform operations comprising:
obtaining a plurality of enhanced multilayer direct disassembly networks (MDDNs);
transforming the plurality of enhanced MDDNs into corresponding knowledge graphs; and
training a machine learning model using the corresponding knowledge graphs.

10. The system of claim 9, wherein training the machine learning model comprises:
training a generative component of the machine learning model using the knowledge graphs; and
training a discriminator component of the machine learning model using the knowledge graphs.

11. The system of claim 10, wherein the operations further comprise:
generating a synthetic disassembly network structure using the generative component; and
classifying the synthetic disassembly network structure using the discriminator component.

12. The system of claim 11, wherein the operations further comprise:
in response to determining that the discriminator component classified the synthetic disassembly network structure as synthetic, updating one or more parameters of the generative component based on feedback from the discriminator component.

13. The system of claim 11, wherein the operations further comprise:
determining whether the discriminator component misclassified the synthetic disassembly network structure; and
in response to determining that the synthetic disassembly network structure was misclassified, updating one or more parameters of the discriminator component based on feedback from a loss evaluation module.

14. The system of claim 9, wherein the plurality of enhanced multilayer direct disassembly networks (MDDNs) includes an enhanced base MDDN generated by:
obtaining a computer-aided design (CAD) assembly file representing an assembly of components;
determining pairs of components in contact by calculating surface-to-surface distances below a predefined threshold;
generating a contact matrix wherein rows and columns correspond to components, and matrix entries indicate contact relationships;
converting the contact matrix into a contact graph comprising nodes representing components and edges representing contact relationships; and
generating a collision result comprising part cluster information by applying a machine learning clustering algorithm to the contact graph.

15. The system of claim 9, wherein the plurality of enhanced multilayer direct disassembly networks (MDDNs) includes a first enhanced simulated MDDN generated by:
obtaining a computer-aided design (CAD) assembly file representing an assembly of components;
determining pairs of components in contact by calculating surface-to-surface distances below a predefined threshold;
determining non-separable component pairs based on first degradation data;
generating a first contact matrix wherein rows and columns correspond to components, and matrix entries indicate contact relationships;
converting the first contact matrix into a first contact graph comprising nodes representing components and edges representing contact relationships; and
generating a first collision result comprising part cluster information by applying a machine learning clustering algorithm to the first contact graph,
wherein non-separable component pairs are represented as a single component in the first contact matrix.

16. The system of claim 15, wherein the plurality of enhanced multilayer direct disassembly networks (MDDNs) includes a second enhanced simulated MDDN generated by:
obtaining the computer-aided design (CAD) assembly file representing an assembly of components;
determining pairs of components in contact by calculating surface-to-surface distances below a predefined threshold;
determining non-separable component pairs based on second degradation data, wherein the second degradation data is different from the first degradation data;
generating a second contact matrix wherein rows and columns correspond to components, and matrix entries indicate contact relationships;
converting the second contact matrix into a second contact graph comprising nodes representing components and edges representing contact relationships; and
generating a second collision result comprising part cluster information by applying a machine learning clustering algorithm to the second contact graph,
wherein non-separable component pairs are represented as a single component in the second contact matrix.

17. A system for generating computer-aided design (CAD) assembly files, comprising:
a memory storing instructions; and
a processor configured to execute the instructions to:
receive input data comprising a multilayer direct disassembly network (MDDN) and a target part specification;
process the MDDN and the target part specification using a generative model to produce a revised MDDN optimized for accessibility of the target part;
convert the revised MDDN into a CAD assembly file; and
present the CAD assembly file to a user via a user interface.

18. The system of claim 17, wherein the user interface is further configured to receive user feedback regarding the CAD assembly file.

19. The system of claim 18, wherein the generative model is updated or retrained based on the received user feedback to improve future design generation.

20. The system of claim 17, wherein the generative model is initially trained by a plurality of enhanced MDDNs.
